(19) United States
(12) Patent Application Publication
(10) Pub. No.: US 2026/0333667 A1
(43) Pub. Date: Oct. 22, 2026

(54) SEMICONDUCTOR DEVICE

(71) Applicant: SAMSUNG ELECTRONICS CO., LTD., Suwon-si (KR)

(72) Inventors: Sukhwa Jang, Suwon-si (KR); Seongeun Park, Suwon-si (KR); Jimin Choi, Suwon-si (KR)

(73) Assignee: SAMSUNG ELECTRONICS CO., LTD., Suwon-si (KR)

(21) Appl. No.: 19/423,393

(22) Filed: Dec. 17, 2025

(30) Foreign Application Priority Data
Apr. 22, 2025 (KR) 10-2025-0052661

(51) Int. Cl. H10B 12/00; H10D 1/68

(52) U.S. Cl. CPC H10B 12/315; H10B 12/34; H10B 12/482; H10B 12/488; H10B 12/50; H10D 1/716; H10B 12/0335

(57) ABSTRACT

A semiconductor device includes a substrate including a cell region in which a plurality of active regions are defined, a peripheral circuit region surrounding the cell region, and a dummy region positioned between the cell region and the peripheral circuit region, a word line, bit line structures in the cell and dummy regions, storage contacts, landing pads, capacitors, and dam structures in the dummy region, the dam structures being arranged in an island pattern and being spaced apart from each other, in a plan view, in the dummy region. The dam structures are between the bit line structures in the dummy region, or the dam structures overlap one or more of the bit line structures in the dummy region.

### CROSS-REFERENCE TO RELATED APPLICATION

This application claims priority to and the benefit of Korean Patent Application No. 10-2025-0052661 filed with the Korean Intellectual Property Office on Apr. 22, 2025, the entire contents of which being herein incorporated by reference.

### BACKGROUND

The present disclosure relates to a semiconductor device.

There is a need for technologies to increase degrees of integration of semiconductor devices.

In the case of two-dimensional semiconductor devices, the degrees of integration are mainly determined by the regions occupied by unit memory cells, and the degrees of integration in this aspect may depend on the levels of micropatterning techniques.

Micropatterning techniques require expensive equipment. Therefore, although the degrees of integration of two-dimensional semiconductor devices are increasing, it is still limited.

Accordingly, three-dimensional memory devices having memory cells arranged in three dimensions are being proposed.

As components which are included in semiconductor memory devices become more integrated and miniaturized, it is advantageous to minimize the influence between components included in semiconductor devices to improve the operating performance of the semiconductor devices.

### SUMMARY

It is an aspect to provide a semiconductor device with improved reliability and productivity.

According to an aspect of one or more embodiments, there is provided a semiconductor device comprising a substrate including a cell region in which a plurality of active regions are defined, a peripheral circuit region surrounding the cell region, and a dummy region positioned between the cell region and the peripheral circuit region, a word line in the cell region, the word line extending in a first direction across the plurality of active regions in the cell region, a plurality of bit line structures in the cell region and the dummy region, the plurality of bit line structures extending in a second direction that intersects the first direction and being connected to the plurality of active regions, a plurality of storage contacts in the cell region and connected to the plurality of active regions, a plurality of landing pads on the plurality of storage contacts, a plurality of capacitors on the plurality of landing pads, and a plurality of dam structures in the dummy region, the plurality of dam structures being arranged in an island pattern and being spaced apart from each other, in a plan view, in the dummy region. The plurality of dam structures are between the plurality of bit line structures in the dummy region, or the plurality of dam structures overlap at least one of the plurality of bit line structures in the dummy region.

According to another aspect of one or more embodiments, there is provided a semiconductor device comprising a substrate including a cell region in which a plurality of active regions are defined, a peripheral circuit region surrounding the cell region, and a dummy region positioned between the cell region and the peripheral circuit region, a word line in the cell region, the word line extending in a first direction across the plurality of active regions in the cell region, a plurality of bit line structures in the cell region and the dummy region, the plurality of bit line structures extending in a second direction that intersects the first direction and being connected to the plurality of active regions, a plurality of storage contacts in the cell region and connected to the plurality of active regions, a plurality of landing pads on the plurality of storage contacts, a plurality of capacitors on the plurality of landing pads, and a plurality of dam structures arranged in as island pattern spaced apart from each other, in a plan view, in the dummy region. The plurality of bit line structures includes a plurality of first bit line structures, each having one end portion thereof positioned in the peripheral circuit region, and a plurality of second bit line structures that are between the plurality of first bit line structures and that each have one end portion thereof which is positioned in the dummy region. The plurality of dam structures are positioned between the plurality of first bit line structures in the dummy region, or each of the plurality of dam structures is positioned to overlap at least one of the plurality of first bit line structures or the plurality of second bit line structures in the dummy region.

According to yet another aspect of one or more embodiments, there is provided a semiconductor device comprising a substrate including a cell region in which a plurality of active regions are defined, a peripheral circuit region surrounding the cell region, and a dummy region positioned between the cell region and the peripheral circuit region, a word line in the cell region, the word line extending in a first direction across the plurality of active regions in the cell region, a plurality of bit line structures in the cell region and the dummy region, the plurality of bit line structures extending in a second direction that intersects the first direction and being connected to the plurality of active regions, a plurality of storage contacts in the cell region and connected to the plurality of active regions, a plurality of landing pads on the plurality of storage contacts, a plurality of capacitors on the plurality of landing pads, a dummy landing pad in the dummy region, a plurality of dam structures arranged in an island pattern spaced apart from each other, in a plan view, in the dummy region, and a plurality of bit line pads spaced apart in the first direction in the peripheral circuit region and connected to the plurality of bit line structures. The plurality of bit line structures includes a plurality of first bit line structures, each having one end portion thereof which is positioned in the peripheral circuit region, the one end portions of the plurality of bit line structures being connected to the plurality of bit line pads, and a plurality of second bit line structures between the plurality of first bit line structures, each having one end portion thereof which is positioned in the dummy region. The plurality of dam structures are between the plurality of first bit line structures in the dummy region and overlap the one end portions of the plurality of second bit line structures.

### BRIEF DESCRIPTION OF THE DRAWINGS

FIG. 1 is a plan view of a semiconductor device according to an embodiment.

FIG. 2 is a plan view illustrating a portion of a semiconductor device according to an embodiment.

FIG. 3 is an enlarged plan view of region R1 of FIG. 1.

FIG. 4 is an enlarged plan view of region R2 of FIG. 1.

FIG. 5 is a plan view illustrating an enlarged portion of FIG. 4.

FIG. 6 is a cross-sectional view illustrating a cross-section taken along lines A-A’ and B-B’ of FIG. 3.

FIG. 7 is a cross-sectional view illustrating a cross-section taken along lines C-C’ and D-D’ of FIG. 4.

FIG. 8 is a cross-sectional view illustrating a cross-section taken along line E-E’ of FIG. 4.

FIGS. 9 to 16 are enlarged plan views illustrating portions of semiconductor devices according to some embodiments.

FIGS. 17 to 31 are cross-sectional views illustrating a manufacturing method of the semiconductor device according to an embodiment.

### DETAILED DESCRIPTION

Hereinafter, various embodiments will be described in detail with reference to the attached drawings so that a person having ordinary skill in the art may easily implement the various embodiments. Aspects of the present disclosure may be embodied in many different forms and the present disclosure is not limited to the embodiments described herein.

In order to clearly explain the various embodiments, parts irrelevant to the description are omitted, and the same reference numerals are used for identical or similar components throughout the specification.

In addition, the size and thickness of each component shown in the drawing are arbitrarily shown for convenience of explanation, so the sizes and thicknesses of components are not necessarily limited to what is shown. To clearly represent the various layers and regions in the drawing, the thickness is enlarged and shown. In the drawings, for convenience of explanation, the thickness of some layers and regions is exaggerated.

Also, when a part, such as a layer, membrane, region, or plate, is described as “over” or “on” another part, this description includes not only cases where the part is “directly over” the other part, but also cases where there are other parts in between. Conversely, when a part is described as “directly above” another part, this description means that there is no other part in between. Being “above” or “on” a reference part means being positioned above or below the reference part, and does not necessarily mean being positioned “above” or “on” the opposite direction of gravity.

Additionally, throughout the specification, whenever a part is said to “include” a component, this description does not mean that the part excludes other components, but rather that the part may include other components, unless otherwise specifically stated.

Additionally, throughout the specification, “in plan” denotes the target portion is viewed from above, and “in cross section” denotes the target portion is viewed from the side in a cross-section cut vertically. As used in this specification, a phrase using the form “at least one of A, B, or C” includes within its scope “only A”, “only B”, “only C”, “A and B”, “A and C”, “B and C” and “A, B, and C.”

According to various embodiments, dam structures positioned in a dummy region are spaced apart from each other in a planar island pattern, which may prevent bit lines included in each of adjacent bit line structures from being electrically shorted to each other by the dam structures.

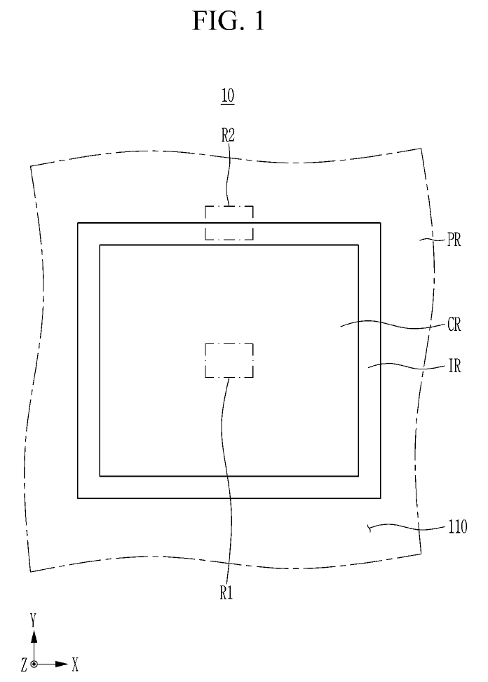

Hereinafter, a semiconductor device according to an embodiment will be described with reference to FIGS. 1 to 8.

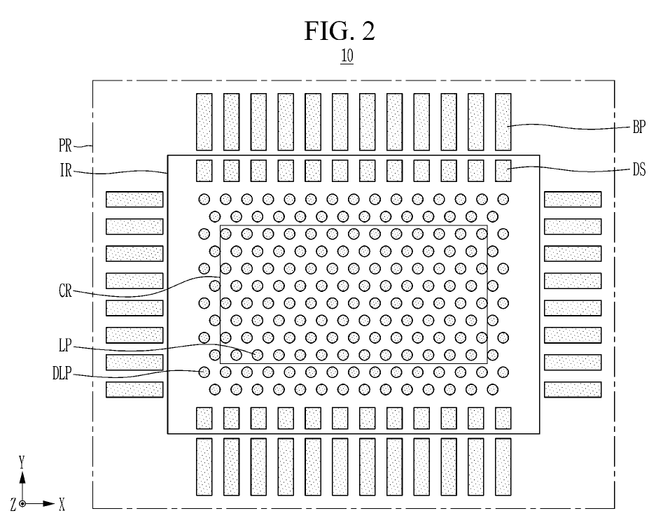

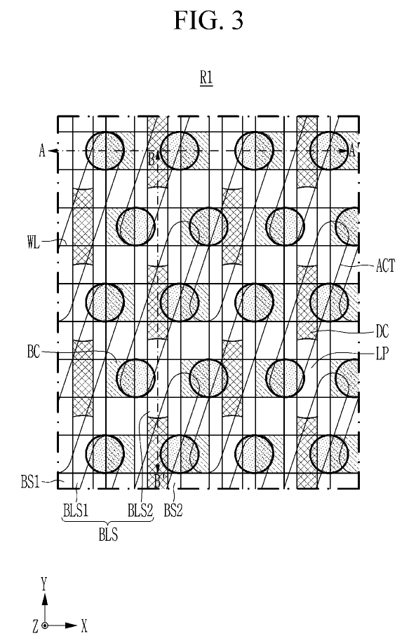

FIG. 1 is a plan view of a semiconductor device according to an embodiment. FIG. 2 is a plan view illustrating a portion of a semiconductor device according to an embodiment. FIG. 3 is an enlarged plan view of region R1 of FIG. 1.

Referring to FIGS. 1 to 3, a substrate 110 of a semiconductor device 10 according to an embodiment may include a cell region CR in which a plurality of active regions ACT are defined, a peripheral circuit region PR surrounding the cell region CR, and a dummy region IR positioned between the cell region CR and the peripheral circuit region PR.

The substrate 110 may have an upper surface parallel to the first direction X and the second direction Y, and may have a thickness parallel to the third direction Z perpendicular to the first direction X and the second direction Y.

The substrate 110 may contain a semiconductor material. For example, the substrate 110 may contain a group IV semiconductor, a group III-V compound semiconductor, a group II-VI compound semiconductor, etc. For example, the substrate 110 may contain a semiconductor such as Si, Ge, or a compound semiconductor such as SiGe, SiC, GaAs, InAs, or InP. For example, the substrate 110 may be a silicon-on-insulator (SOI substrate) or a germanium-on-insulator (GOI substrate). However, the material of the substrate 110 is not limited to this and may be variously changed.

A plurality of memory cells may be positioned in the cell region CR. At least one of a memory cell of a volatile memory device and a memory cell of a non-volatile memory device may be positioned in the cell region CR.

A plurality of memory cells for storing information may be positioned in a cell region CR. A memory cell may include at least one transistor and at least one capacitor. Depending on the presence or absence of charge stored in the capacitor, two distinct states are determined, allowing the capacitor to act as a memory element.

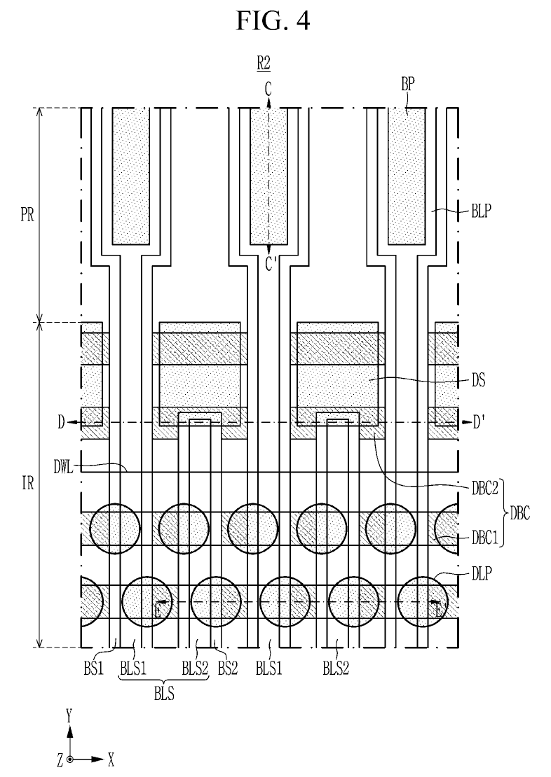

In an embodiment, the cell region CR may include a plurality of bit line structures (see ‘BLS’ in FIG. 3), a plurality of word lines (see ‘WL’ in FIG. 3), a plurality of storage contacts (see ‘BC’ in FIG. 3), a plurality of landing pads LP, and a plurality of capacitors (see ‘CAP’ in FIG. 4), and the plurality of bit line structures (see ‘BLS’ in FIG. 3), the plurality of word lines (see ‘WL’ in FIG. 3), the plurality of storage contacts (see ‘BC’ in FIG. 3), and the plurality of landing pads LP may be connected to a plurality of unit memory cells positioned in the cell region CR.

As illustrated in FIG. 2, in an embodiment, the plurality of landing pads LP positioned in the cell region CR may be arranged in a honeycomb shape in a plan view, by being spaced apart in a zigzag pattern in the first direction X or the second direction Y in a plan view.

In an embodiment, the cell region CR may include memory cells of volatile memory devices, such as Dynamic Random Access Memory (DRAM). For example, the memory cells of a Buried Channel Array Transistor (BCAT) DRAM may be positioned in the cell region CR. However, embodiments are not limited to this type, and the type of memory device may be variously changed.

For example, memory cells of 3D memory devices such as DRAM including a Vertical Channel Transistor (VCT), VS DRAM (Vertically Stacked DRAM), 3D FeFET (Ferroelectric FET), 3D monolithic, etc. may be positioned in the cell region CR.

As another example, memory cells of a non-volatile memory device, such as NAND flash, may be positioned in a cell region CR.

As another example, the cell region CR may include various types of devices such as FINFET (Fin Field Effect Transistor), GAA-FET (e.g., MBCFET^{TM} (Multi Bridge Channel Field Effect Transistor)), 3DS-FET (3D Stack Field Effect Transistor), and CFET (Complementary Field Effect Transistor).

Below, it is assumed that a semiconductor device 10 according to an embodiment has a Buried Channel Array Transistor (BCAT) DRAM structure.

The peripheral circuit region PR may be positioned adjacent to a cell region CR. The peripheral circuit region PR may be positioned at least one side of a cell region CR. For example, as illustrated in FIGS. 1 and 2, the peripheral circuit region PR may entirely surround the cell region CR in a plan view. However, the arrangement relationship between the cell region CR and the peripheral circuit region PR is not limited to this arrangement and may be variously changed.

For example, the peripheral circuit region PR may partially surround the cell region CR in a plan view.

The peripheral circuit region PR may be positioned adjacent to the cell region CR and may be a region where circuits used for driving the semiconductor device 10 or reading/writing a plurality of memory cells included in the semiconductor device 10.

The peripheral circuit region PR may include a core region and a peri region. That is, the peripheral circuit region PR may be called the core/peri region or the logic region.

The core region may include a core bank, and a core bank may include core circuits such as a word line driver, a sense amplifier, a row decoder, a column decoder, and a read/write circuit.

The peri region may include peri circuits such as timing registers, address registers, data input registers, data output registers, and data input/output terminals.

Additionally, although not illustrated in detail, peripheral circuitry may be positioned in the peripheral circuit region PR. The peripheral circuitry may include, for example, a sensing transistor, a transmission transistor, and/or a driving transistor. However, the type of transistor in the peripheral circuitry positioned in the peripheral circuit region PR is not limited to these types and may be variously changed depending on the design of the semiconductor device.

As illustrated in FIG. 2, in an embodiment, a plurality of peripheral circuit wirings BP may be positioned in the peripheral circuit region PR.

The plurality of peripheral circuit wirings BP may extend in the first direction X in peripheral circuit regions PR positioned on both sides of a first direction X of a cell region CR, and may extend in a second direction Y in peripheral circuit regions PR positioned on both sides of a second direction Y of the cell region CR.

The plurality of peripheral circuit wirings BP extending in the first direction X in peripheral circuit regions PR positioned on both sides of the first direction X of the cell region CR may connect a plurality of word lines (see ‘WL’ in FIG. 3) positioned in the cell region CR and peripheral circuits positioned in the peripheral circuit region PR. For example, a peripheral circuit connected to the plurality of word lines (‘WL’ in FIG. 3) may be a word line driver circuit.

The plurality of peripheral circuit wirings BP extending in the second direction Y in peripheral circuit regions PR positioned on both sides of the second direction Y of the cell region CR may connect the plurality of bit line structures (see ‘BLS’ in FIG. 3) positioned in the cell region CR and peripheral circuits positioned in the peripheral circuit region PR. For example, peripheral circuits connected to the plurality of bit line structures (‘BLS’ in FIG. 3) may be sensing circuits.

The dummy region IR may be positioned between the cell region CR and the peripheral circuit region PR. For example, in an embodiment, the dummy region IR may entirely surround the cell region CR in a plan view. However, embodiments are not limited to this surrounding structure, and the dummy region IR may partially surround the cell region CR.

The semiconductor device 10 according to an embodiment may include a plurality of dam structures DS and a plurality of dummy landing pads DLP positioned in the dummy region IR.

In an embodiment, the plurality of dam structures DS may be arranged in the first direction X in dummy regions IR positioned on both sides of the second direction Y of the cell region CR. The plurality of dam structures DS may be spaced apart from each other and may be arranged in an island pattern in a plan view. That is, for example, in some embodiments, the island pattern may denote that the dam structures DS are separated and arranged along an outside edge of the dummy region IR, as around an outside edge of an island, as shown in FIG. 2. In some embodiment, the island pattern may denote that the plurality of dam structures DS are separated from each other into individually separated islands.

As illustrated in FIG. 2, in an embodiment, a plurality of dam structures DS is arranged only in dummy regions IR positioned on both sides of the second direction Y of the cell region CR, and are not arranged in dummy regions IR positioned on both sides of the first direction X of the cell region CR, but the arrangement of the plurality of dam structures DS is not limited thereto.

Unlike as illustrated in FIG. 2, in some embodiments, the plurality of dam structures DS may extend in the second direction Y in the dummy regions IR positioned on both sides of the first direction X of the cell region CR, and may have a line shape or a bar shape in a plan view.

As another example, a plurality of dam structures DS in a dummy region IR positioned on both sides of the first direction X of the cell region CR may be arranged in an island pattern, spaced apart from each other in the second direction Y in a plan view.

In an embodiment, the plurality of dummy landing pads DLP positioned in a dummy region IR may be arranged to surround the cell region CR in a plan view.

A planar arrangement of the plurality of dummy landing pads DLP may be substantially identical to a planar arrangement of the plurality of landing pads LP positioned in the cell region CR. That is, the plurality of dummy landing pads DLP may be arranged in a planar honeycomb pattern in the dummy region IR, by being spaced apart in a zigzag pattern in the first direction X and the second direction Y.

The plurality of dummy landing pads DLP arranged in a dummy region IR positioned on both sides of the second direction Y of the cell region CR may be positioned between the plurality of landing pads LP positioned in the cell region CR and the plurality of dam structures DS positioned in the dummy region IR in a plan view.

The plurality of dam structures DS arranged in dummy regions IR positioned on both sides of the second direction Y of the cell region CR may be positioned between the plurality of dummy landing pads DLP and the plurality of peripheral circuit wirings BP positioned in a peripheral circuit region PR in a plan view.

Accordingly, the plurality of dummy landing pads DLP in the dummy region IR may be arranged adjacent to the cell region CR, and the plurality of dam structures DS may be arranged adjacent to the peripheral circuit region PR.

In an embodiment, the plurality of landing pads LP positioned in the cell region CR, the plurality of dam structures DS and the plurality of dummy landing pads DLP positioned in the dummy region IR, and the plurality of peripheral circuit wirings BP positioned in the peripheral circuit region PR may be formed using the same material in the same process step.

Accordingly, the plurality of landing pads LP, the plurality of dam structures DS, the plurality of dummy landing pads DLP, and the plurality of peripheral circuit wirings BP may be positioned at substantially the same level and may contain the same material. A more detailed description thereof will be provided later.

By forming the plurality of dam structures DS and the plurality of dummy landing pads DLP in a dummy region IR positioned between the cell region CR and the peripheral circuit region PR, it is possible to reduce process difficulty caused by a difference in pattern density between the cell region CR and the peripheral circuit region PR, and to make the pattern density in each of the cell region CR and the peripheral circuit region PR more uniform.

Hereinafter, the configuration and structure of a semiconductor device 10 according to an embodiment will be described in detail.

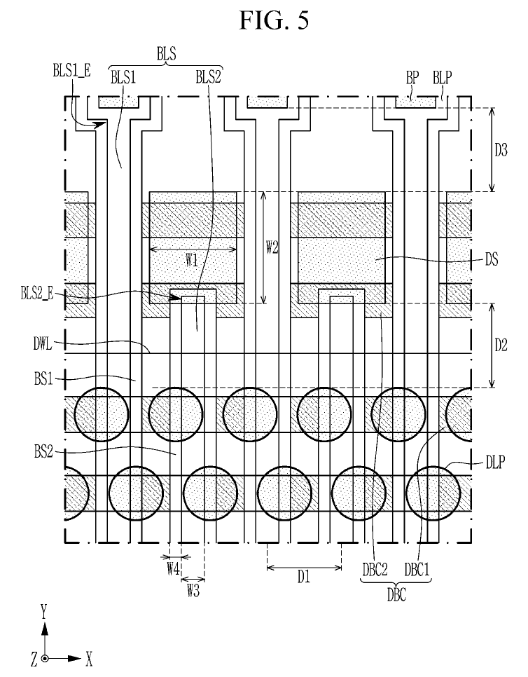

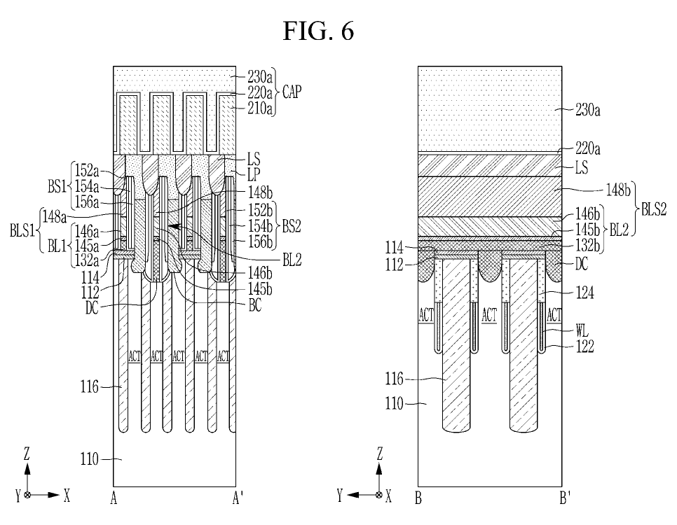

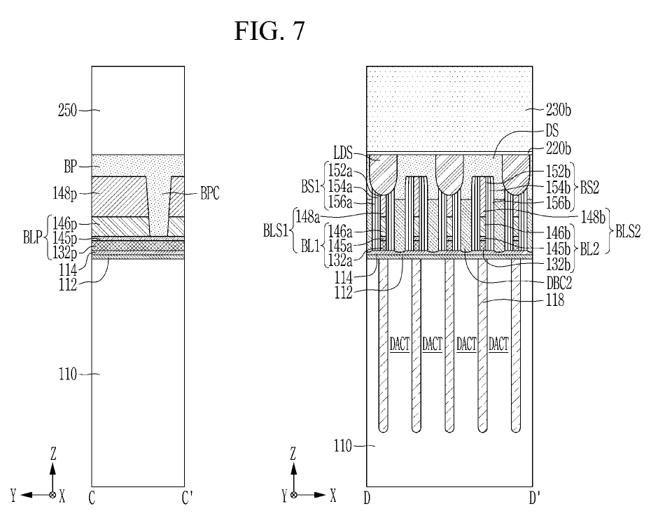

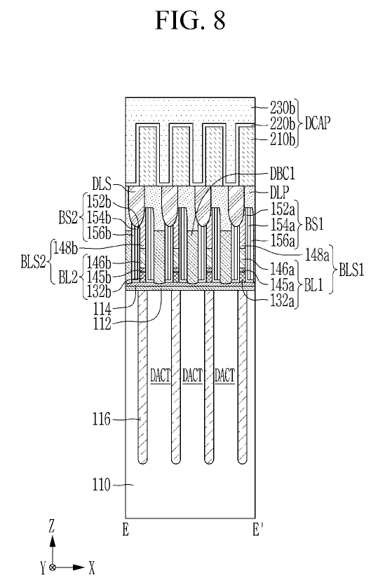

FIG. 3 is an enlarged plan view of region R1 of FIG. 1. FIG. 4 is an enlarged plan view of region R2 of FIG. 1. FIG. 5 is a plan view showing an enlarged portion of a part of FIG. 4. FIG. 6 is a cross-sectional view showing a section taken along lines A-A’ and B-B’ of FIG. 3. FIG. 7 is a cross-sectional view showing a section taken along lines C-C’ and D-D’ of FIG. 4. FIG. 8 is a cross-sectional view showing a section taken along line E-E’ of FIG. 4.

Referring to FIGS. 3 to 8, the semiconductor device 10 according to an embodiment may include the plurality of active regions ACT positioned in the cell region CR of the substrate 110, a plurality of word lines WL extending in a first direction X across the plurality of active regions ACT in the cell region CR, a plurality of bit line structures BLS extending in a second direction Y intersecting the first direction X in the cell region CR and the dummy region IR, a plurality of storage contacts BC positioned between adjacent bit line structures BLS in the cell region CR, a plurality of landing pads LP positioned on the plurality of storage contacts BC, and a plurality of capacitors CAP positioned on the plurality of landing pads LP.

The semiconductor device 10 according to an embodiment may include the plurality of dam structures DS arranged in an island pattern in a plan view and spaced apart from each other in the dummy region IR of the substrate 110, and may include a bit line pad BLP positioned in the peripheral circuit region PR of the substrate 110 and connected to the bit line structure BLS.

First, the configurations positioned in the cell region CR of the substrate 110 are described.

As illustrated in FIG. 3, the semiconductor device 10 according to an embodiment may include the plurality of active regions ACT positioned in the cell region CR of the substrate 110.

The plurality of active regions ACT may be formed by patterning the substrate 110. The plurality of active regions ACT may extend from an upper surface toward a lower surface of the substrate 110 in a cross-sectional view.

Each of the plurality of active regions ACT may have a bar shape extending in an oblique diagonal direction with respect to a first direction X and a second direction Y in a plan view.

Here, the diagonal direction is parallel to the upper surface of the substrate 110 and may be positioned on the substantially same plane as the first direction X and the second direction Y. For example, the diagonal direction may form an acute angle with the first direction X and the second direction Y, respectively.

The plurality of active regions ACT may be two-dimensionally arranged in the first direction X and the diagonal direction oblique to the first direction X and the second direction Y. That is, the plurality of active regions ACT may be arranged to be spaced apart from each other at predetermined intervals in the first direction X and the oblique diagonal direction.

The center of one active region ACT may be adjacent to an end portion of another active region ACT in the first direction X. One end portion of one active region ACT may be adjacent to the other end portion of another active region ACT in the first direction X. However, the shape of the active region ACT or the planar arrangement is not limited thereto and may be variously changed.

As illustrated in FIG. 6, the semiconductor device 10 according to an embodiment may further include a device isolation layer 116 defining the active region ACT in the cell region CR of the substrate 110.

The plurality of active regions ACT positioned in the substrate 110 may be separated from each other by the device isolation layer 116, and the device isolation layer 116 may be positioned between adjacent active regions ACT.

The device isolation layer 116 may have a Shallow Trench Isolation (STI) structure having excellent element isolation characteristics. The device isolation layer 116 may contain silicon oxide, silicon nitride, or a combination thereof. However, the material of the device isolation layer 116 is not limited to these materials and may be variously changed.

The device isolation layer 116 may have a single-layer or multi-layer structure. That is, the device isolation layer 116 may have a single-layer structure including a single insulating material, or a multi-layer structure including two or more types of insulating materials.

The semiconductor device 10 according to an embodiment may include the plurality of word lines WL.

The plurality of word lines WL may extend in the first direction X across the plurality of active regions ACT in the cell region CR of the substrate 110 and may be arranged spaced apart from each other in the second direction Y in a plan view.

One word line WL extends in the first direction X to overlap a plurality of active regions ACT and may serve as a gate electrode.

One active region ACT may cross-overlap two word lines WL. One active region ACT may be divided into three portions by two word lines WL.

Here, the center portion of the active region ACT positioned between two word lines WL may be a portion connected to the bit line structure BLS described later, and both end portions of the active region ACT positioned outside the two word lines WL may be portions connected to the plurality of landing pads LP.

As illustrated in FIG. 6, the semiconductor device 10 according to an embodiment may further include a word line insulating pattern 122 surrounding the word line WL and a word line capping layer 124 positioned on the word line WL.

As illustrated in FIG. 6, the word line insulating pattern 122 may be conformally positioned along the inner side surface of the word line trench that recesses a portion of the active region ACT in the cell region CR of the substrate 110.

The word line insulating pattern 122 may contain an insulating material. For example, the word line insulating pattern 122 may contain silicon oxide, silicon nitride, silicon oxynitride, a high-k material having a higher dielectric constant than silicon oxide, or a combination thereof. However, the arrangement and material of the word line insulating pattern 122 are not limited thereto and may be variously changed.

The word line WL may fill a portion of a word line trench where the word line insulating pattern 122 is formed. The word line insulating pattern 122 may surround the lower surface and both side surfaces of the word line WL. The upper surface of the word line WL may be positioned at a lower level than the upper surface of the active region ACT and the upper surface of the device isolation layer 116.

The word line WL may contain a conductive material. For example, the word line WL may contain Ti, TiN, Ta, TaN, W, WN, TiSiN, WSiN, polysilicon, or a combination thereof. However, the arrangement and material of the word line WL are not limited thereto and may be variously changed.

In an embodiment, the word line WL is illustrated as having a single-layer structure, but is not limited thereto. The word line WL may have a multilayer structure including at least two types of conductive materials among the conductive materials described above.

The word line capping layer 124 may be positioned on the word line insulating pattern 122 and the word line WL.

The word line capping layer 124 may fill the remaining area of the word line trench where the word line insulating pattern 122 and the word line WL are formed.

The word line capping layer 124 may cover the upper surface of the word line insulating pattern 122 and the upper surface of the word line WL. The upper surface of the word line capping layer 124 may be positioned at substantially the same level as the upper surface of the active region ACT and the upper surface of the device isolation layer 116.

The word line capping layer 124 may be positioned between the word line WL and a bit line contact DC to be described later. The word line WL and the bit line contact DC may be insulated by a word line capping layer 124.

The word line capping layer 124 may contain an insulating material. For example, the word line capping layer 124 may contain silicon oxide, silicon nitride, silicon oxynitride, or a combination thereof. However, the arrangement and material of the word line capping layer 124 are not limited thereto and may be variously changed. For example, both sides of the word line capping layer 124 may be surrounded by the word line insulating pattern 122.

As illustrated in FIGS. 3-5, the semiconductor device 10 according to an embodiment may include the plurality of bit line structures BLS.

The plurality of bit line structures BLS may be arranged spaced apart in the first direction X and extending in the second direction Y across the plurality of active regions ACT positioned in the cell region CR of the substrate 110 in a plan view. That is, the bit line structure BLS is insulated from the word line WL and may extend across the word line WL in a different direction.

The bit line structure BLS may be positioned on the word line WL. One bit line structure BLS may extend in the second direction Y to overlap the plurality of adjacent active regions ACT in the second direction Y.

The bit line structure BLS may be connected to the active region ACT by a bit line contact DC, which will be described later. The center portion of each of the plurality of active regions ACT may be connected to the bit line structure BLS. However, embodiments are not limited to this connection structure, and the connection structure of the bit line structure BLS and the active region ACT may be variously changed.

In an embodiment, the plurality of bit line structures BLS may extend in the second direction Y from the cell region CR to the dummy region IR and the peripheral circuit region PR.

Specifically, as illustrated in FIGS. 3 to 5, the plurality of bit line structures BLS may include a plurality of first bit line structures BLS1 extending in one direction in the second direction Y from the cell region CR to the peripheral circuit region PR and having one end portion BLS1_E positioned in the peripheral circuit region PR, and a plurality of second bit line structures BLS2 extending in one direction in the second direction Y from the cell region CR to the dummy region IR and having one end portion BLS2_E positioned in the dummy region IR.

Here, one end portion BLS1_E of the first bit line structure BLS1 may refer to an end portion of the first bit line structure BLS1 and a portion adjacent thereto, and one end portion BLS2_E of the second bit line structure BLS2 may refer to an end portion of the second bit line structure BLS2 and a portion adjacent thereto.

Although not illustrated in detail in FIGS. 4 and 5, one end portion BLS1_E of the first plurality of bit line structures BLS1 may be positioned in the peripheral circuit region PR at one side of the second direction Y of the cell region CR, and the other end portion may be positioned in the dummy region IR at the other side of the second direction Y of the cell region CR.

The first plurality of bit line structures BLS1 extend in the second direction Y in the cell region CR, the dummy region IR, and the peripheral circuit region PR, and one end portion BLS1_E may be positioned in the peripheral circuit region PR at one side of the cell region CR in the second direction Y, and the other end portion may be positioned in the dummy region IR at the other side of the cell region CR in the second direction Y.

One end portion BLS2_E of the second plurality of bit line structures BLS2 may be positioned in the dummy region IR at one side in the second direction Y of the cell region CR, and the other end portion may be positioned in the peripheral circuit region PR at the other side in the second direction Y of the cell region CR.

One end portion BLS1_E of the first plurality of bit line structures BLS1 may be connected to the bit line pad BLP positioned in the peripheral circuit region PR at one side in the second direction Y of the cell region CR.

Although not illustrated in detail in FIGS. 4 and 5, the other end portion of the second plurality of bit line structures BLS2 may be connected to the bit line pad BLP positioned in the peripheral circuit region PR on the other side in the second direction Y of the cell region CR. A more detailed description thereof will be provided later.

The first bit line structure BLS1 may include a sequentially stacked first bit line BL1 and a first bit line capping pattern 148a.

The first bit line BL1 may include a first bit line conductive layer 132a, a second bit line conductive layer 145a, and a third bit line conductive layer 146a that are sequentially stacked.

The first bit line conductive layer 132a, the second bit line conductive layer 145a, and the third bit line conductive layer 146a may have different thicknesses in the third direction Z. However, embodiments are not limited thereto, and at least two of the first bit line conductive layer 132a, the second bit line conductive layer 145a, and the third bit line conductive layer 146a may have substantially the same thickness in the third direction Z.

Each of the first bit line conductive layer 132a, the second bit line conductive layer 145a, and the third bit line conductive layer 145a of the first bit line BL1 may contain a conductive material. For example, the first bit line conductive layer 132a may contain polysilicon doped with impurities or a metal such as W, Mo, Au, Cu, Al, Ni, or Co, the second bit line conductive layer 145a may contain a metal such as Ti, Ta, or the like and/or a metal nitride such as TiN, TaN, or the like, and the third bit line conductive layer 146a may contain a metal such as W, Mo, Au, Cu, Al, Ni, or Co. However, the number and material of the conductive layers constituting the first bit line BL1 are not limited thereto and may be variously changed.

The first bit line capping pattern 148a may be positioned on the first bit line BL1. The first bit line capping pattern 148a may be positioned on the third bit line conductive layer 146a of the first bit line BL1.

The first bit line capping pattern 148a may contain an insulating material. For example, the first bit line capping pattern 148a may contain silicon oxide, silicon nitride, silicon oxynitride, or a combination thereof. However, the material contained in the first bit line capping pattern 148a is not limited thereto and may be variously changed.

In FIG. 6, the first bit line capping pattern 148a is illustrated as having a single-layer structure, but embodiments are not limited thereto. The first bit line capping pattern 148a may include at least two kinds of the insulating materials described above and may have a multi-layer structure having different thicknesses in the third direction Z.

The second bit line structure BLS2 may include a sequentially stacked second bit line BL2 and a second bit line capping pattern 148b.

The second bit line BL2 may include a first bit line conductive layer 132b, a second bit line conductive layer 145b, and a third bit line conductive layer 146b that are sequentially stacked.

The first bit line conductive layer 132a of the first bit line BL1 may have substantially the same thickness as the first bit line conductive layer 132b of the second bit line BL2 and may contain the same material, the second bit line conductive layer 145a of the first bit line BL1 may have substantially the same thickness as the second bit line conductive layer 145b of the second bit line BL2, and the third bit line conductive layer 146a of the first bit line BL1 may have substantially the same thickness as the third bit line conductive layer 146b of the second bit line BL2.

The second bit line capping pattern 148b may be positioned on the second bit line BL2. The second bit line capping pattern 148b may be positioned on the third bit line conductive layer 146b of the second bit line BL2.

The first bit line capping pattern 148a has substantially the same thickness as the second bit line capping pattern 148b and may contain the same material.

The description of the first bit line capping pattern 148a described above may be substantially equally applied to the second bit line capping pattern 148b, and therefore, a detailed description thereof is omitted for conciseness.

The semiconductor device 10 according to an embodiment may further include a plurality of bit line contacts DC positioned between the bit line structure BLS and the active region ACT.

The plurality of bit line contacts DC may be positioned between the bit line structure BLS and the active region ACT. Bit lines BL1 and BL2 included in the bit line structure BLS may be electrically connected to the active region ACT through bit line contacts DC.

Specifically, the bit line contact DC may be positioned between the bit lines BL1 and BL2 and the center portion of the active region ACT. For example, the bit line contact DC may be positioned between the first bit line conductive layer 132b of the second bit line BL2 and the active region ACT.

In FIG. 6, the bit line contact DC is illustrated as being positioned between the second bit line BL2 and the active region ACT, but in some embodiments, the bit line contact DC may also be positioned between the first bit line BL1 and the active region ACT. That is, the bit line contact DC may also be positioned between the first bit line conductive layer 132a of the first bit line BL1 and the active region ACT.

The bit line contact DC may recess the active region ACT and the device isolation layer 116 in the cell region CR. The bit line contact DC may recess the active region ACT and the word line capping pattern 124 in the cell region CR.

Accordingly, the bit line contact DC may be positioned to overlap the active region ACT, a portion of the word line insulating pattern 122, and a portion of the word line capping layer 124 in the third direction Z.

The lower surface of the bit line contact DC may be at a lower level than the upper surface of the substrate 110. The lower surface of the bit line contact DC may be positioned at a higher level than the upper surface of the word line WL. However, the arrangement relationship between the word line WL, the word line insulating pattern 122, and the word line capping layer 124 and the bit line contact DC is not limited thereto and may be variously changed.

The bit line contact DC may contain a conductive material. For example, the bit line contact DC may contain polysilicon doped with impurities or a metal such as W, Mo, Au, Cu, Al, Ni, Co, etc. However, the material contained in the bit line contact DC is not limited to these materials and may be variously changed.

In an embodiment, the bit line contact DC may be portion of the bit lines BL1 and BL2. The bit line contact DC may be portion of the first conductive layers 132a and 132b of each of the bit lines BL1 and BL2. That is, the bit line contact DC and the first bit line conductive layers 132a and 132b may contain the same material. For example, the first bit line conductive layers 132a and 132b and the bit line contact DC may contain polysilicon doped with impurities.

In FIG. 6, a boundary is illustrated between the bit line contact DC and the first bit line conductive layer 132b of the second bit line BL2. However, if the bit line contact DC and the first bit line conductive layers 132a and 132b contain the same material and the bit line contact DC forms portion of the bit lines BL1 and BL2, a boundary may not be visually identifiable between the bit line contact DC and the first bit line conductive layer 132b of the second bit line BL2. However, the disclosure is not limited thereto, and the bit line contact DC and the first bit line conductive layers 132a and 132b may contain different materials, and a boundary therebetween may be visually distinguishable.

The semiconductor device 10 according to an embodiment may further include a first buffer layer 112 and a second buffer layer 114 sequentially stacked between the first bit line BL1 and the substrate 110 and between the second bit line BL2 and the substrate 110.

The first buffer layer 112 and the second buffer layer 114 may be positioned on the device isolation layer 116 and the active region ACT. For example, the first buffer layer 112 and the second buffer layer 114 may be positioned between the device isolation layer 116 and the bit lines BL1 and BL2, and may not be positioned between the active region ACT and the bit line contact DC.

In an embodiment, the widths of each of the first buffer layer 112 and the second buffer layer 114 in the first direction X are substantially the same, and the widths of each of the first buffer layer 112 and the second buffer layer 114 in the first direction X may be greater than the widths of each of the bit line structures BLS1 and BLS2in the first direction X. However, embodiments are not limited thereto, and the widths of the first buffer layer 112 and the second buffer layer 114 in the first direction X may be different.

Unlike as illustrated in FIG. 6, the width of the first buffer layer 112 in the first direction X may be larger than the width of each of the bit line structures BLS1 and BLS2in the first direction X, and the width of the second buffer layer 114 in the first direction X may be substantially equal to the width of each of the bit line structures BLS1 and BLS2in the first direction X.

Each of the first buffer layer 112 and the second buffer layer 114 may contain an insulating material. For example, each of the first buffer layer 112 and the second buffer layer 114 may contain silicon oxide, silicon nitride, silicon oxynitride, or a combination thereof. However, the materials contained in each of the first buffer layer 112 and the second buffer layer 114 are not limited thereto and may be variously changed.

In some embodiments, either one of the first buffer layer 112 and the second buffer layer 114 may be omitted to have a single-layer structure, or a multi-layer structure including three or more layers including buffer layers other than the first buffer layer 112 and the second buffer layer 114 may be provided.

The semiconductor device 10 according to an embodiment may include the plurality of storage contacts BC positioned between the plurality of bit line structures BLS.

The plurality of storage contacts BC may be arranged spaced apart in the first direction X and the second direction Y. For example, the plurality of storage contacts BC may be arranged in a matrix pattern in the first direction X and the second direction Y in a plan view.

In FIG. 3, the storage contact BC is illustrated as having a square shape in a plan view, but embodiments are not limited thereto, and the storage contact BC may have various shapes such as a circle, an ellipse, a diamond, and a hexagon in a plan view.

The storage contact BC may be positioned to fill portion of the region between adjacent bit line structures BLS1 and BLS2. At least a portion of the storage contact BC may overlap the active region ACT in the third direction Z, and the remaining portion may overlap the device isolation layer 116 in the third direction Z.

The storage contact BC may recess a portion of the active region ACT and the portion of the device isolation layer 116. The lower surface of the storage contact BC may be positioned at a lower level than the lower surface of the first buffer layer 112. The lower surface of the storage contact BC may be positioned at a lower level than the upper surface of the active region ACT and the upper surface of the device isolation layer 116.

The storage contact BC may overlap at least a portion of each of the bit line structures BLS1 and BLS2in the first direction X. The upper surface of the storage contact BC may be positioned at a level between the upper surface and the lower surface of each of the bit line capping patterns 148a and 148b. However, the levels of each of the lower and upper surfaces of the storage contact BC are not limited to this configuration and may be variously changed.

The storage contact BC may directly contact the active region ACT. At least a portion of the lower surface and side surfaces of the storage contact BC may be surrounded by an active region ACT. However, embodiments are not limited to this structure, and other layers may be positioned between the storage contact BC and the active region ACT, and the storage contact BC may be connected to the active region ACT through other configurations.

The storage contact BC may contain a conductive material. For example, the storage contact BC may contain doped polysilicon, but embodiments are not limited thereto.

The semiconductor device 10 according to an embodiment may further include a first spacer structure BS1 positioned on a side surface of a first bit line structure BLS1 and a second spacer structure BS2 positioned on a side surface of a second bit line structure BLS2.

The first spacer structure BS1 may extend along the side surface of the first bit line structure BLS1, and the second spacer structure BS2 may extend along the side surface of the second bit line structure BLS2.

The first spacer structure BS1 may be positioned between the first bit line structure BLS1 and the storage contact BC and between the first bit line structure BLS1 and the landing pad LP. The second spacer structure BS2 may be positioned between the second bit line structure BLS2 and the storage contact BC and between the second bit line structure BLS2 and the landing pad LP.

Each of the first spacer structure BS1 and the second spacer structure BS2 may have a multilayer structure composed of a combination of various types of insulating materials.

Specifically, the first spacer structure BS1 may include a first spacer 152a, a second spacer 154a, and a third spacer 156a. The second spacer structure BS2 may include a first spacer 152b, a second spacer 154b, and a third spacer 156b.

The first spacer 152a of the first spacer structure BS1 may extend along the side surface of the first bit line structure BLS1 and may be in contact with the side surface of the first bit line structure BLS1, and the first spacer 152b of the second spacer structure BS2 may extend along the side surface of the second bit line structure BLS2 and may be in contact with the side surface of the second bit line structure BLS2.

The first spacer 152a of the first spacer structure BS1 may cover a portion of the upper surface of the second buffer layer 114. In addition, although not illustrated in detail in FIG. 6, the first spacer 152b of the second spacer structure BS2 may cover a portion of the upper surface of the second buffer layer 114.

The first spacer 152a of the first spacer structure BS1 and the first spacer 152b of the second spacer structure BS2 may extend along the side surface of the bit line contact DC. For example, as illustrated in FIG. 6, the first spacer 152b of the second spacer structure BS2 may extend along the bottom surface of the bit line contact trench that recesses the active region ACT and the device isolation layer 116, and may cover the side surface of the bit line contact DC.

Although not illustrated in detail in FIG. 6, the first spacer 152a of the first spacer structure BS1 may cover the side surface of the bit line contact DC substantially identically to the first spacer 152b of the second spacer structure BS2.

The second spacer 154a of the first spacer structure BS1 may extend along the surface of the first spacer 152a of the first spacer structure BS1, and the second spacer 154b of the second spacer structure BS2 may extend along the surface of the first spacer 152b of the second spacer structure BS2.

As illustrated in FIG. 6, the second spacer 154b of the second spacer structure BS2 may fill the remaining area where the first spacer 152b is formed in the bit line contact trench described above, and may overlap the bit line contact DC in the first direction X. The lower surface of the second spacer 154b of the second spacer structure BS2 may be covered by the first spacer 152a.

Although not illustrated in detail in FIG. 6, the second spacer 154a of the first spacer structure BS1 may fill the remaining area after the first spacer 152a is formed in the bit line contact trench described above, substantially the same as the second spacer 154b of the second spacer structure BS2, and may overlap with the bit line contact DC in the first direction X.

The third spacer 156a of the first spacer structure BS1 may be positioned between the second spacer 154a and the storage contact BC and between the second spacer 154a and the landing pad LP. The third spacer 156a may extend along the surface of the second spacer 154a.

Accordingly, the second spacer 154a may be positioned between the first spacer 152a and the third spacer 156a of the first spacer structure BS1.

The third spacer 156a of the first spacer structure BS1 may directly contact the storage contact BC and the landing pad LP. However, embodiments are not limited thereto, and other configurations may be further positioned between the third spacer 156a of the first spacer structure BS1 and the storage contact BC and between the third spacer 156a and the landing pad LP.

The third spacer 156b of the second spacer structure BS2 may be positioned between the second spacer 154b and the storage contact BC and between the second spacer 154b and the landing pad LP. The third spacer 156b may extend along the surface of the second spacer 154b.

Accordingly, the second spacer 154b may be positioned between the first spacer 152b and the third spacer 156b of the second spacer structure BS2.

The third spacer 156b of the second spacer structure BS2 may be in contact with the storage contact BC and the landing pad LP. However, embodiments are not limited thereto, and other configurations may be further positioned between the third spacer 156b of the second spacer structure BS2 and the storage contact BC, and between the third spacer 156b and the landing pad LP.

In some embodiments, the second spacers 154a and 154b of each of the first spacer structure BS1 and the second spacer structure BS2 may be air gaps. That is, each of the second spacers 154a and 154b of the first spacer structure BS1 and the second spacer structure BS2 may be an air spacer defined between the first spacer 152a and the third spacer 156a of the first spacer structure BS1 and between the first spacer 152b and the third spacer 156b of the second spacer structure BS2.

The first spacer structure BS1 may contain an insulating material. For example, at least some of the first spacer 152a, the second spacer 154a, and the third spacer 156a may contain different materials.

As a more specific example, the first spacer 152a, the second spacer 154a, and the third spacer 156a may contain silicon nitride, silicon oxynitride, silicon oxide, silicon carbonate, silicon carbon nitride, silicon carbonate, or a combination thereof. For example, the first spacer 152a and the third spacer 156a may contain silicon nitride, and the second spacer 154a may contain silicon oxide. However, the number and material of the spacers constituting the first spacer structure BS1 are not limited thereto and may be variously changed.

Although the description is based on the first spacer structure BS1, the description of the first spacer structure BS1 may be substantially equally applied to the first spacer 152b, the second spacer 154b, and the third spacer 156b constituting the second spacer structure BS2, and therefore a detailed description thereof is omitted for conciseness.

For example, the first spacer 152a of the first spacer structure BS1 may contain the same material as the first spacer 152b of the second spacer structure BS2, the second spacer 154a of the first spacer structure BS1 may contain the same material as the second spacer 154b of the second spacer structure BS2, and the third spacer 156a of the first spacer structure BS1 may contain the same material as the third spacer 156b of the second spacer structure BS2.

The semiconductor device 10 according to an embodiment may include the plurality of landing pads LP positioned on the plurality of storage contacts BC in a cell region CR.

As illustrated in FIG. 3, the plurality of landing pads LP may be arranged spaced apart from each other in the first direction X and the second direction Y.

Specifically, the plurality of landing pads LP may be arranged in a row in the first direction X, and the plurality of landing pads LP may be arranged in a zigzag pattern in the second direction Y. For example, the bit line structure BLS may be arranged alternately on one side and the other side of the first direction X in the second direction Y. However, the arrangement of the plurality of landing pads LP in a plan view is not limited to this configuration and may be variously changed.

In FIG. 3, each of the plurality of landing pads LP is illustrated as having a circular shape in a plan view, but embodiments are not limited thereto, and each of the plurality of landing pads LP may have various shapes such as an oval, rectangle, square, diamond, and hexagon in a plan view.

In an embodiment, the plurality of landing pads LP may be positioned to overlap at least a portion of each of the plurality of storage contacts BC.

Specifically, the landing pad LP may be positioned to overlap a portion of the storage contact BC. The landing pad LP may be positioned to overlap a portion of the upper surface of the storage contact BC. That is, a portion of the landing pad LP may overlap the bit line structure BLS and the spacer structures BS1 and BS2 in the third direction Z, and the remaining portion may overlap the storage contact BC in the third direction Z.

The landing pads LP may be positioned between adjacent bit line structures BLS. That is, the landing pads LP may fill the upper region between adjacent bit line structures BLS.

The landing pad LP covers the bit line structures BLS1 and BLS2 and the spacer structures BS1 and BS2, and an interface between the landing pad LP and the storage contact BC may be positioned at a level between a lower surface and an upper surface of each of the bit line capping patterns 148a and 148b of the bit line structures BLS1 and BLS2.

The landing pad LP may in contact with the storage contact BC. The landing pad LP may be electrically connected to the active region ACT the storage contact BC.

The landing pad LP may contain a conductive material. The landing pad LP may contain at least one of a metal such as tungsten (W), doped polysilicon, a conductive metal nitride, a conductive metal silicon nitride, a metal carbonitride, a conductive metal silicide, a conductive metal oxide, and a two-dimensional material.

In FIG. 6, the landing pad LP is illustrated as having a single-layer structure, but embodiments are not limited thereto. For example, the landing pad LP may have a multilayer structure in which the plurality of conductive materials is stacked.

When the landing pad LP has a multilayer structure, one of the plurality of conductive material layers may contain Ti, TiN, or a combination thereof, and another layer of the plurality of conductive material layers may contain a metal such as W, a metal nitride, polysilicon doped with impurities, or a combination thereof. However, the materials of the landing pad LP are not limited to these materials and may be variously changed.

Although not illustrated in detail in FIG. 6, some embodiments may further include a barrier layer conformally positioned between the landing pad LP and the spacer structures BS1 and BS2 and between the landing pad LP and the storage contact BC.

The barrier layer may contain a metal nitride. The contact barrier layer may contain, for example, one of titanium nitride (TiN), tantalum nitride (TaN), or tungsten nitride (WN).

The semiconductor device 10 according to an embodiment may further include a landing pad insulating pattern LS positioned between adjacent landing pads LP.

The landing pad insulating pattern LS may fill the space between landing pads LP. The landing pad insulating pattern LS may surround the side surfaces of the landing pad LP. The landing pad insulating pattern LS is positioned between adjacent landing pads LP and may be a node isolation pattern that electrically isolates and insulates the adjacent landing pads LP.

The landing pad insulating pattern LS may recess a portion of each of the bit line structures BLS1 and BLS2and the spacer structures BS1 and BS2.

The landing pad insulating pattern LS may contain an insulating material including silicon nitride, silicon oxynitride, silicon oxide, or a combination thereof. For example, the landing pad insulating pattern LS may contain silicon nitride. However, the arrangement and material of the landing pad insulating pattern LS are not limited thereto and may be variously changed.

In FIG. 6, the landing pad insulating pattern LS is illustrated as being formed of a single layer structure but embodiments are not limited thereto.

In some embodiments, the landing pad insulating pattern LS may include a plurality of layers. For example, the landing pad insulating pattern LS may include a first material layer and a second material layer that are stacked.

In this case, the first material layer may contain a low-k material having a low dielectric constant, such as silicon oxide, SiOH, or SiOC, and the second material layer may contain silicon nitride or silicon oxynitride.

The semiconductor device 10 according to an embodiment may include the plurality of capacitors CAP each positioned on the plurality of landing pads LP.

The plurality of capacitors CAP may be positioned to overlap completely or partially with each of the plurality of landing pads LP in the third direction Z. For example, the plurality of capacitors CAP may be positioned to overlap a portion of each of the plurality of landing pads LP. Each of the plurality of capacitors CAP may be electrically connected to the active region ACT through the landing pad LP and the storage contact BC.

The capacitor CAP may include a first electrode 210a, a second electrode 230a, and a dielectric film 220a positioned between the first electrode 210a and the second electrode 230a.

The first electrode 210a may be connected to the landing pad LP. The first electrode 210a may extend in the third direction Z on the landing pad LP.

The first electrode 210a may contain a metal, a conductive metal nitride, or a combination thereof. For example, the first electrode 210a may contain TiN, Ru, TaN, WN, Pt, Ir, or a combination thereof. However, the material contained in the first electrode 210a is not limited thereto and may be variously changed.

The dielectric film 220a may extend conformally along the upper surface and side profile of the first electrode 210a. That is, the dielectric film 220a may cover the side surface and upper surface of the first electrode 210a. The dielectric film 220a may cover the upper surface of the landing pad LP and the upper surface of the landing pad insulating pattern LS.

The dielectric film 220a may contain tantalum oxide (Ta₂O₅), aluminum oxide (Al₂O₃), titanium oxide (TiO₂), or a combination thereof. However, embodiments are not limited thereto, and the material contained in the dielectric film 220a may be variously changed.

The second electrode 230a may be positioned on the dielectric film 220a. The second electrode 230a may entirely cover the first electrode 210a. That is, the second electrode 230a may cover the upper surface and side surface of the first electrode 210a.

The second electrode 230a may contain a metal material such as W, Ti, Ru, SiGe, etc. For example, the second electrode 230a may contain tungsten (W). However, the material contained in the second electrode 230a is not limited thereto and may be variously changed. For example, the second electrode 230a may contain a conductive metal nitride, a metal silicide, or a combination thereof.

Hereinafter, the configuration and structure positioned in the dummy region IR and peripheral circuit region PR of the substrate 110 are described in detail.

The semiconductor device 10 according to an embodiment may further include a plurality of dummy active regions DACT defined in the dummy region IR, a dummy storage contact DBC positioned in the dummy region IR, and the dummy landing pad DLP positioned on the dummy storage contact DBC.

As illustrated in FIGS. 7 and 8, the plurality of dummy active regions DACT may be formed by patterning the substrate 110 in the dummy region IR. The plurality of dummy active regions DACT may extend from an upper surface toward a lower surface of the substrate 110 in a cross-sectional view.

Although not illustrated in detail in FIGS. 4 and 5, the plurality of dummy active regions DACT positioned in the dummy region IR have substantially the same planar shape as the active region ACT positioned in the cell region CR described above, and may have substantially the same planar array shape.

This configuration may be a result of patterning the dummy active region DACT together with the dummy region IR of the substrate 110 in a process step of forming the active region ACT in the cell region CR of the substrate 110.

Specifically, each of the plurality of dummy active regions DACT may have a bar shape extending in a diagonal direction oblique to the first direction X and the second direction Y in a plan view.

Here, the diagonal direction is parallel to the upper surface of the substrate 110 and may be positioned on substantially the same plane as the first direction X and the second direction Y. For example, the diagonal direction may form an acute angle with the first direction X and the second direction Y, respectively.

The plurality of dummy active regions DACT may be two-dimensionally arranged in the first direction X and a diagonal direction oblique to the first direction X and the second direction Y. That is, the plurality of dummy active regions DACT may be spaced apart from each other at predetermined intervals in the first direction X and an oblique diagonal direction relative to the first direction X and second direction Y.

Although not illustrated in detail in FIGS. 4 and 5, both end portions of the dummy active region DACT in the diagonal direction oblique to the first direction X and the second direction Y may be connected to the dummy storage contact DBC. However, embodiments are not limited thereto, and the planar shape of the active region ACT positioned in the cell region CR may be different from the planar shape of the dummy active region DACT positioned in the dummy region IR, or at least one of the planar arrangement and densities of the plurality of active regions ACT positioned in the cell region CR may be different from the planar arrangement and density of the plurality of dummy active regions DACT positioned in the dummy region IR.

According to an embodiment of the semiconductor device 10, a dummy device isolation layer 118 positioned between adjacent dummy active regions DACT may be further included.

The plurality of dummy active regions DACT positioned in the dummy region IR of the substrate 110 may be separated from each other by the dummy device isolation layer 118, and the dummy device isolation layer 118 may be positioned between adjacent dummy active regions DACT.

Since the description of the device isolation layer 116 positioned in the cell region CR may be substantially equally applied to the dummy device isolation layer 118 positioned in the dummy region IR, a detailed description thereof is omitted for conciseness.

The semiconductor device 10 according to an embodiment may include a plurality of dummy word lines DWL positioned in a dummy region IR.

As illustrated in FIG. 4, the plurality of dummy word lines DWL may extend in a first direction X in a dummy region IR of the substrate 110 and be positioned spaced apart from each other in a second direction Y.

Although not illustrated in detail in FIG. 4, the plurality of dummy word lines DWLs may extend in the first direction X to across the plurality of dummy active regions DACT.

The semiconductor device 10 according to an embodiment may include the plurality of dummy storage contacts DBC positioned between the plurality of bit line structures BLS in the dummy region IR.

As illustrated in FIGS. 4 and 5, the plurality of dummy storage contacts DBC may include a plurality of first dummy storage contacts DBC1 and a plurality of second dummy storage contacts DBC2 having different shapes in a plan view.

Specifically, the plurality of first dummy storage contacts DBC1 may be positioned between the first bit line structure BLS1 and the second bit line structure BLS2 which are adjacent to each other in the dummy region IR. The plurality of first dummy storage contacts DBC1 may be positioned between the plurality of dummy word lines DWL adjacent in the second direction Y.

The plurality of second dummy storage contacts DBC2 may be positioned between adjacent first bit line structures BLS1 in the dummy region IR.

The plurality of second dummy storage contacts DBC2 may be positioned spaced apart in the first direction X with the first bit line structures BLS1 interposed therebetween, and spaced apart in the second direction Y between adjacent first bit line structures BLS1.

Some of the plurality of second dummy storage contacts DBC2 may surround an end portion BLS2_E of the second bit line structure BLS2 in a plan view.

The first dummy storage contact DBC1 may have substantially the same planar shape as that of the plurality of storage contacts BC positioned in the cell region CR as described above with reference to FIG. 3, and may also have substantially the same planar arrangement as that of the storage contacts BC positioned in the cell region CR.

The planar shape of the plurality of second dummy storage contacts DBC2 may be different from the planar shape of the first dummy storage contact DBC1. For example, the first dummy storage contact DBC1 may have a square shape in a plan view. Some of the plurality of second dummy storage contacts DBC2 may be rectangular bar-shaped having a major axis in the first direction X and a minor axis in the second direction Y in a plan view, and the remaining some may be rectangular shape in a plan view including a groove surrounding an end portion BLS2_E of the second bit line structure BLS2.

Accordingly, the planar area of the first dummy storage contact DBC1 and the planar area of the second dummy storage contact DBC2 may be different. For example, the planar area of the first dummy storage contact DBC1 may be smaller than the planar area of the second dummy storage contact DBC2. However, embodiments are not limited thereto, and the relationship between the planar shape and/or area of the first dummy storage contact DBC1 and the second dummy storage contact DBC2 may be variously changed.

This configuration may be a result of differences in the patterning environment or arear due to the configurations positioned around the region where the first dummy storage contact DBC1 and the second dummy storage contact DBC2 are formed in the dummy region IR.

As illustrated in FIGS. 7 and 8, in an embodiment, the first buffer layer 112 and the second buffer layer 114 may be positioned to extend from the cell region CR to the dummy region IR. The first buffer layer 112 and the second buffer layer 114 may cover the upper surface of each of the dummy active region DACT and the dummy device isolation layer 118.

Dummy storage contacts DBC1 and DBC2 may be positioned on the second buffer layer 114. Dummy storage contacts DBC1 and DBC2 may recess the upper surface of the second buffer layer 114.

Accordingly, the lower surface of each of the dummy storage contacts DBC1 and DBC2 may include a curved surface. However, embodiments are not limited thereto, and the lower surface of each of the dummy storage contacts DBC1 and DBC2 may have a straight shape.

The first dummy storage contact DBC1 extends in the third direction Z between the first bit line structure BLS1 and the second bit line structure BLS2 which are adjacent to each other, and may fill part of a region between the first bit line structure BLS1 and the second bit line structure BLS2.

The first dummy storage contact DBC1 may be positioned between the first spacer structure BS1 and the second spacer structure BS2, which are adjacent to each other, and may be in contact with the first spacer structure BS1 and the second spacer structure BS2 that are adjacent to each other. However, embodiments are not limited to this configuration, and other configurations may be positioned between the first dummy storage contact DBC1 and the spacer structures BS1 and BS2.

Some of the plurality of second dummy storage contacts DBC2 may extend in the third direction Z between the adjacent first bit line structures BLS1 and second bit line structures BLS2, and may fill part of a region between the first bit line structures BLS1 and the second bit line structures BLS2.

Some of the plurality of second dummy storage contacts DBC2 may be positioned between the first spacer structure BS1 and the second spacer structure BS2, which are adjacent to each other, and may be in contact with the first spacer structure BS1 and the second spacer structure BS2 that are adjacent to each other. However, embodiments are not limited to this configuration, and other configurations may be further positioned between some of the plurality of second dummy storage contacts DBC2 and the spacer structures BS1 and BS2.

Some of the remaining second dummy storage contacts DBC2 may extend in the third direction Z between the adjacent first bit line structures BLS1 and fill some of the region between the adjacent first bit line structures BLS1.

Some of the remaining second dummy storage contacts DBC2 may be positioned between and may be in contact with the adjacent first spacer structures BS1. However, embodiments are not limited thereto, and other configurations may be further positioned between the remaining portions of the plurality of second dummy storage contacts DBC2 and the first spacer structure BS1.

In an embodiment, the plurality of first dummy storage contacts DBC1 and the plurality of second dummy storage contacts DBC2 positioned in the dummy region IR may be formed together in the same process using the same material as the plurality of storage contacts BC positioned in the cell region CR.

Accordingly, each of the first dummy storage contact DBC1 and the second dummy storage contact DBC2 positioned in the dummy region IR may contain the same conductive material as the storage contact BC positioned in the cell region CR.

A description of the materials of the first and second dummy storage contacts DBC1 and DBC2 is omitted for conciseness since the same or substantially the same applies to the storage contact BC.

The upper surface of each of the first dummy storage contact DBC1 and the second dummy storage contact DBC2 positioned in the dummy region IR may be positioned at substantially the same level as the upper surface of the storage contact BC positioned in the cell region CR. For example, the upper surface of the first dummy storage contact DBC1 and the upper surface of the second dummy storage contact DBC2 may be positioned at a level between the lower surface and the upper surface of each of the bit line capping patterns 148a and 148b of the bit line structures BLS.

Accordingly, since the plurality of dummy storage contacts DBC are formed in the dummy region IR positioned between the cell region CR and the peripheral circuit region PR, the process difficulty due to the difference in the density of the patterns positioned in each of the cell region CR and the peripheral circuit region PR may be reduced, and the pattern density positioned in each of the cell region CR and the peripheral circuit region PR may be made uniform.

In the dummy region IR, each of the plurality of dummy landing pads DLP may be positioned on the plurality of first dummy storage contacts DBC1.

Each of the planar shape and the planar arrangement of the plurality of dummy landing pads DLP positioned in the dummy region IR may be substantially the same as the planar shape and the planar arrangement of the plurality of landing pads LP positioned in the cell region CR.

That is, each of the plurality of dummy landing pads DLP positioned in the dummy region IR has a circular shape in a plan view, and each of the plurality of dummy landing pads DLP may be arranged to overlap a portion of the plurality of first dummy storage contacts DBC1.

The arrangement relationship between the first dummy storage contact DBC1 and the bit line structures BLS1 and BLS2, and the arrangement relationship between the first dummy storage contact DBC1 and the spacer structures BS1 and BS2, may be substantially the same as the arrangement relationship between the storage contact BC and the bit line structures BLS1 and BLS2, and between the dummy storage contact DBC and the spacer structures BS1 and BS2 in the cell region CR. Accordingly, a detailed description thereof will be omitted for conciseness.

In an embodiment, the plurality of dam structures DS may be arranged in an island pattern spaced apart from each other in the dummy region IR in a plan view. That is, the plurality of dam structures DS may be arranged to be separated from each other in the dummy region IR. That is, the island pattern may denote that the dam structures DS are separated from each other into separate “islands” in plan view.

Here, the dummy region IR may refer to a dummy region IR positioned on one side of the second direction Y. For example, a description of the plurality of dam structures DS and bit line structures BLS1 and BLS2 may refer to the plurality of dam structures DS and bit line structures BLS1 and BLS2 arranged in a dummy region IR positioned on one side in the second direction Y.

The plurality of dam structures DS may be positioned between the plurality of bit line structures BLS in the dummy region IR, or the plurality of dam structures DS may be arranged to overlap at least a portion of the plurality of bit line structures BLS in the dummy region IR, respectively, in the third direction Z.

In an embodiment, the plurality of dam structures DS may be arranged such that some of the bit line structures BLS positioned in the dummy region IR overlap each other in the third direction Z.

Specifically, as illustrated in FIGS. 4 and 5, the plurality of dam structures DS are positioned between adjacent first bit line structures BLS1 in the dummy region IR, and may be positioned to overlap the second bit line structures BLS2 extending between the adjacent first bit line structures BLS1, in the third direction Z.

Accordingly, the plurality of dam structures DS may be positioned so as to not overlap with the first bit line structures BLS1 among the plurality of bit line structures BLS positioned in the dummy region IR and to overlap with the plurality of second bit line structures BLS2, in the third direction Z.

The plurality of dam structures DS may be positioned to overlap an end portion BLS2_E of the second bit line structures BLS2. That is, the plurality of dam structures DS may be positioned to overlap the end portion BLS2_E of the second bit line structures BLS2 and the second spacer structures BS2 surrounding the second bit line structures BLS2, in the third direction Z.

The plurality of dam structures DS may be positioned to overlap the second dummy storage contacts DBC2 positioned between adjacent first bit line structures BLS2 in the dummy region IR in the third direction Z. For example, as shown in FIGS. 4 and 5, the plurality of dam structures DS may be positioned to overlap, in the third direction Z, the plurality of second dummy storage contacts DBC2 that are spaced apart from each other in the second direction Y.

As illustrated in FIG. 7, each of the plurality of dam structures DS may cover the upper surface and the side surface adjacent thereto of the second bit line structure BLS2. Each of the plurality of dam structures DS may cover a portion of the second spacer structure BS2 positioned in an upper region of the second bit line structure BLS2.

The plurality of dam structures DS may be positioned between, and may be in contact with, the first spacer structure BS1 and the second spacer structure BS2, which are adjacent to each other. For example, one side surface of each of the plurality of dam structures DS may be in contact with the first spacer structure BS1, and the other side surface may be in contact with the second spacer structure BS2.

The plurality of dam structures DS may be positioned between and may be in contact with adjacent first spacer structures BS1. For example, both side surfaces of a portion of each of the plurality of dam structures DS may be in contact with the first spacer structure BS1. However, embodiments are not limited to this configuration, and other configurations may be positioned between the plurality of dam structures DS and the first and second spacer structures BS1 and BS2.

The plurality of dam structures DS may cover the upper surface of the second dummy storage contacts DBC2. For example, as illustrated in FIG. 7, each of the plurality of dam structures DS may cover the upper surface of the second dummy storage contact DBC2 positioned on both side surfaces of the first bit line structure BLS1.

Accordingly, a portion of the dam structure DS is positioned at a level higher than the upper surface of the bit line structure BLS, and the remaining part is positioned at a level lower than the upper surface of the bit line structure BLS and may be in contact with the upper surface of the second dummy storage contact DBC2. However, embodiments are not limited thereto, and in another configuration, the portion of the dam structure DS may be further positioned at least one of between the dam structure DS and the bit line structure BLS, between the dam structure DS and the spacer structures BS1 and BS2, or between the dam structure DS and the second dummy storage contact DBC2.

Unlike as shown in FIG. 7, each of the plurality of dam structures DS may be positioned at a level higher than the upper surface of the plurality of bit line structures BLS. That is, the lower surface of each of the plurality of dam structures DS may be positioned at substantially the same level as the upper surface of the bit line capping patterns 148a and 148b of each of the bit line structures BLS.

Accordingly, each of the plurality of dam structures DS is positioned on the upper surfaces of the plurality of bit line structures BLS and the upper surfaces of the spacer structures BS1 and BS2, and may not be positioned between adjacent bit line structures BLS.

As such, when the plurality of dam structures DS are positioned at a level higher than the upper surface of the bit line structure BLS, the lower surface of the plurality of dam structures DS may be positioned at a level higher than the second dummy storage contact DBC2 positioned adjacent to the bit line structure BLS.

In an embodiment, each of the plurality of dam structures DS may have a rectangular shape having a short axis in the first direction X and a long axis in the second direction Y in a plan view. However, the planar shape of the plurality of dam structures DS is not limited to this structure. For example, each of the plurality of dam structures DS may have a shape in which the corners have a curvature in a plan view.

As another example, each of the plurality of dam structures DS may have a shape whose side surface includes a curved surface, such as a circle or an ellipse in a plan view.

As another example, each of the plurality of dam structures DS may have a polygonal shape, such as a square, a rhombus, and a hexagon in a plan view.

In an embodiment, the planar area of the dam structure DS positioned in the dummy region IR may be different from the planar area of the landing pad LP positioned in the cell region CR and the planar area of the dummy landing pad DLP positioned in the dummy region IR.

For example, the planar area of the dam structure DS may be larger than the planar area of the landing pad LP positioned in the cell region CR and the planar area of the dummy landing pad DLP positioned in the dummy region IR.

The planar area of the dummy landing pad DLP in the dummy region IR may be larger than the planar area of the landing pad LP positioned in the cell region CR. However, embodiments are not limited thereto, and the relationship between the planar areas of the dam structure DS positioned in the dummy region IR, the dummy landing pad DLP, and the landing pad LP positioned in the cell region CR may be variously changed.

In this way, by forming the planar areas of the dam structures DS and the dummy landing pads DLP, which are positioned in the dummy region IR, to be larger than the planar area of the landing pads LP positioned in the cell region CR, a pattern density between the cell region CR and the peripheral circuit region PR may be made more uniform, and accordingly, the structures formed in the dummy region IR may be patterned more reliably.

In an embodiment, a width of the dam structure DS in the first direction X may be greater than a sum of a width of the second bit line structure BLS2 in the first direction X, which overlaps the dam structure DS in the third direction Z, and widths of each of the second spacer structures BS2 positioned on both sides of the second bit line structure BLS2 in the first direction X.

Accordingly, each of the second bit line structure BLS2 and the second spacer structures BS2 positioned on both sides of the second bit line structure BLS2 may entirely overlap the dam structure DS in the third direction Z.

Specifically, as illustrated in FIG. 3, the dam structure DS may have a first width W1 in the first direction X and a second width W2 in the second direction Y.

The first bit line structure BLS1 may have a third width W3 in the first direction X, and each of the first spacer structures BS1 positioned on sides of the first bit line structure BLS1 may have a fourth width W4 in the first direction X.

Here, the first width W1, the third width W3, and the fourth width W4 may each refer to a maximum width in the first direction X, and the second width W2 may refer to a maximum width in the second direction Y.

In an embodiment, the first width W1 may be greater than the sum of the third width W3 and both fourth widths W4. However, the relationship between the sum of the third width W3 and the fourth widths, and the first width W1 is not limited to this relationship and may be variously changed. For example, the first width W1 may be substantially equal to the sum of the third width W3 and the fourth widths W4, or may be less than the sum of the third width W3 and the fourth widths W4.

In an embodiment, the plurality of bit line structures BLS may be arranged spaced apart by a first distance D1 in the first direction X.

Here, the first distance D1 may refer to a pitch between nearest bit line structures BLS in the first direction X. For example, the first distance D1 may refer to a straight-line distance in the first direction X between the centers of each of the first bit line structures BLS1 and the second bit line structures BLS2 that are nearest to each other.

In an embodiment, the first distance D1 between the bit line structures BLS may be greater than about half the first width W1 of the dam structure DS.

In this case, the relationship between the first distance D1 and the first width W1 may be variously changed. For example, the first distance D1 may be smaller than the first width W1. As another example, the first distance D1 may be greater than the first width W1 or substantially equal to the first width W1. However, the relationship between the first distance D1 and the first width W1 is not limited to these relationships and may be variously changed.

As such, when the first distance D1 is greater than half of the first width W1, it is possible to secure a process margin within an allowable range of misalignment in a process of forming the plurality of dam structures DS, such that adjacent dam structures DS do not come into contact with each other even if any one of the dam structures DS is mis-aligned toward one side in the first direction X.

Unlike as illustrated in FIG. 5, in some embodiments, the first distance D1 between the bit line structures BLS may be greater than about twice the first width W1 of the dam structure DS.

As such, when the first distance D1 is greater than about twice the first width W1, it is possible to secure a process margin within an allowable range of misalignment during a process of forming the plurality of dam structures DS, such that even when one of the adjacent dam structures DS is mis-aligned toward one side in the first direction X and the other is mis-aligned toward the opposite side, the adjacent dam structures DS do not come into contact with each other.

Accordingly, in a process of forming the second bit line structures BLS2 and the second spacer structures BS2 that overlap the plurality of dam structures DS in a third direction Z, even if a portion of the second spacer structure BS2 surrounding the end portion BLS2_E of the second bit line structure BLS2 is over-etched and removed, it is possible to prevent a short from occurring between adjacent second bit line structures BLS2 through mis-aligned and connected dam structures DS.

In an embodiment, the dam structure DS and the dummy landing pad DLP positioned in the dummy region IR may be positioned spaced apart by a second distance D2.

Here, the second distance D2 may refer to the minimum distance in the second direction Y between the dam structure DS and the dummy landing pad LP closest to the dam structure DS. That is, the second distance D2 may refer to a straight-line distance in the second direction Y, between the dam structure DS and the dummy landing pad DLP closest to the dam structure DS.

In an embodiment, the second distance D2 may be greater than about half the second width W2 of the dam structure DS. In this case, the relationship between the second distance D2 and the second width W2 may be variously changed. For example, the second distance D2 may be smaller than the second width W2. As another example, the second distance D2 may be greater than or substantially equal to the second width W2. However, the relationship between the second distance D2 and the second width W2 is not limited to these relationships and may be variously changed.

As described above, when the second distance D2 is greater than half of a second width W2, it is possible to secure a process margin within an allowable range of misalignment during a process of forming the plurality of dam structures DS, such that even if the dam structure DS is mis-aligned in the second direction Y toward the plurality of dummy landing pads DLP, the dam structure DS does not come into contact with the dummy landing pads DLP.

Accordingly, in a process of forming the second bit line structures BLS2 and the second spacer structures BS2 that overlap the plurality of dam structures DS in a third direction Z, even if a portion of the second spacer structure BS2 surrounding the end portion BLS2_E of the second bit line structure BLS2 is over-etched and removed, it is possible to prevent a short from occurring between the second bit line structures BLS2 having partially removed spacer structures BS2 through the mis-aligned and connected dam structures DS and the plurality of dummy landing pads DLP.

As illustrated in FIGS. 4 and 5, in an embodiment, the dam structure DS positioned in a dummy region IR and the peripheral circuit wiring BP positioned in a peripheral circuit region PR may be positioned spaced apart from each other by a third distance D3.

Here, the third distance D3 may refer to the minimum distance in the second direction Y between the dam structure DS positioned in the dummy region IR and the peripheral circuit wiring BP positioned in the peripheral circuit region PR. That is, the third distance D3 may refer to a straight-line distance in the second direction Y between the dam structure DS and the peripheral circuit wiring BP.

In an embodiment, the third distance D3 may be greater than about half the second width W2 of the dam structure DS. In this case, the relationship between the third distance D3 and the second width W2 may be variously changed. For example, the third distance D3 may be smaller than the second width W2. As another example, the third distance D3 may be greater than or substantially equal to the second width W2. However, the relationship between the third distance D3 and the second width W2 is not limited to these relationships and may be variously changed.

As described above, when the third distance D3 is greater than twice the second width W2, it is possible to secure a process margin within an allowable range of misalignment during a process of forming the plurality of dam structures DS, such that even if a dam structure DS is mis-aligned in a second direction Y toward the plurality of peripheral circuit wirings BP, the dam structure DS does not come into contact with the peripheral circuit wirings BP.

Accordingly, during a process of forming the plurality of dam structures DS, it is possible to prevent a short from occurring between adjacent peripheral circuit wirings BP through a mis-aligned dam structure DS.

In an embodiment, the plurality of landing pads LP positioned in the cell region CR, the plurality of dummy landing pads DLP positioned in the dummy region IR, and the plurality of dam structures DS may be formed together in the same process using the same material.

Accordingly, each of the plurality of landing pads LP positioned in the cell region CR, the plurality of dummy landing pads DLP positioned in the dummy region IR, and the plurality of dam structures DS may contain the same conductive material.

The landing pad DLP and dam structure DS positioned in the dummy region IR may contain the same conductive material as the storage contact BC positioned in the cell region CR.

A description of the materials of the dummy landing pad DLP and the dam structure DS is omitted for conciseness since the same or substantially the same applies to the landing pad LP.

In an embodiment, the landing pad LP positioned in the cell region CR and the dummy landing pad DLP and dam structure DS positioned in the dummy region IR may be positioned at substantially the same level. For example, the lower surface of the landing pad LP positioned in the cell region CR may be positioned at substantially the same level as the lower surface of the dummy landing pad DLP positioned in the dummy region IR and the lower surface of the dam structure DS positioned in the dummy region IR.

Here, the lower surface of the landing pad LP may refer to a surface in contact with the storage contact BC, the lower surface of the dummy landing pad DLP may refer to a surface in contact with the first dummy storage contact DBC1, and the lower surface of the dam structure DS may refer to a surface in contact with the second dummy storage contact DBC2.

The upper surface of the landing pad LP positioned in the cell region CR may be positioned at substantially the same level as the upper surface of the dummy landing pad DLP positioned in the dummy region IR and the upper surface of the dam structure DS positioned in the dummy region IR. However, embodiments are not limited thereto, and at least one of the landing pad LP positioned in the cell region CR, the dummy landing pad DLP positioned in the dummy region IR, and the dam structure DS positioned in the dummy region IR may contain a different material, or at least one may be positioned at a different level.

As shown in FIGS. 7-8, the semiconductor device 10 according to an embodiment may further include a dummy insulating pattern DLS positioned between the plurality of dummy landing pads DLP in a dummy region IR and a dam insulating pattern LDS positioned between the plurality of dam structures DS.

The dummy isolating pattern DLS may be positioned between adjacent dummy landing pads DLP. The dummy isolating pattern DLS may fill the space between dummy landing pads DLP. The dummy isolating pattern DLS may surround the side surfaces of the dummy landing pad DLP. The dummy isolating pattern DLS is positioned between adjacent dummy landing pads DLP and may be a node isolation pattern that electrically isolates and insulates the adjacent dummy landing pads DLP.

The dummy insulating pattern DLS may recess into a portion of each of the bit line structures BLS1 and BLS2 and the spacer structures BS1 and BS2.

A lower surface of the dummy insulating pattern DLS may be positioned at a higher level than a lower surface of a dummy landing pad DLP in contact with the first dummy storage contact DBC1, and an upper surface of the dummy insulating pattern DLS may be positioned at substantially the same level as an upper surface of the dummy landing pad DLP.

The dam insulating patterns LDS may be positioned between adjacent dam structures DS. the dam insulating pattern LDS may fill the space between adjacent dam structures DS. The dam insulating pattern LDS may surround the side surfaces of the dam structure DS.

The lower surface of the dam insulating pattern LDS may be positioned at a higher level than the lower surface of the dam structure DS in contact with the second dummy storage contact DBC2, and the upper surface of the dummy insulation pattern DLS may be positioned at substantially the same level as the upper surface of the dam structure DS.

The dam insulating pattern LDS may be positioned between adjacent dam structures DS and may be a node insulation pattern that electrically isolates and insulates the adjacent dam structures DS.

In an embodiment, the dam insulating pattern LDS may recess some of the first and second bit line structures BLS1 and BLS2and some of the first and second spacer structures BS1 and BS2, respectively. For example, as illustrated in FIG. 7, the dam insulating pattern LDS may recess into a portion of each of the plurality of first bit line structures BLS1 and a portion of the first spacer structure BS1 positioned on both sides of the first bit line structure BLS1.

The dam insulating pattern LDS may recess into a portion of the first bit line capping pattern 148a of the first bit line structure BLS1 and a portion of the first spacer structure BS1 positioned on both sides of the first bit line capping pattern 148a. The dummy insulating pattern DLS may be positioned so as not to overlap with the plurality of second bit line structures BLS positioned in the dummy region IR in the third direction Z.

As such, since the portion of the first bit line structure BLS1 in the dummy region IR is recessed by the dam insulating pattern LDS, a length of the first bit line structure BLS1 positioned in the dummy region IR in the third direction Z may be smaller than a length of the second bit line structure BLS2 in the third direction Z.

A width of the dam insulating pattern LDS in the first direction X may be greater than the sum of the width of the first bit line structure BLS1 in the first direction X and the widths of each of the first spacer structures BS1 positioned on both sides of the first bit line structure BLS1 in the first direction X.

Accordingly, the dam insulating pattern LDS recesses the portion of each of the first bit line structure BLS1 and the portion of the first spacer structure BS1, and may overlap the second dummy storage contact DBC2 positioned between the first bit line structure BLS1 and the second bit line structure BLS2 in a third direction Z.

In an embodiment, the landing pad insulating pattern LS positioned in the cell region CR may be formed together with the dummy insulating pattern DLS and the dam insulating pattern LDS positioned in the dummy region IR using the same material in the same process.

Accordingly, the landing pad insulating pattern LS positioned in the cell region CR may contain the same insulation material as the dummy insulating pattern DLS and the dam insulating pattern LDS positioned in the dummy region IR.

A description of the materials of the dummy isolating pattern DLS and the dam isolating pattern LDS is omitted for conciseness since the same or substantially the same applies to the landing pad isolating pattern LS.

In an embodiment, the landing pad insulating pattern LS positioned in the cell region CR and the dummy insulation pattern DLS and dam insulating pattern LDS positioned in the dummy region IR may be positioned at substantially the same level. For example, the lower surface of the landing pad insulating pattern LS positioned in the cell region CR may be positioned at substantially the same level as the lower surface of the dummy insulating pattern DLS positioned in the dummy region IR and the lower surface of the dam insulating pattern LDS.

Here, the level of the lower surface of the landing pad insulating pattern LS, the level of the lower surface of the dummy insulating pattern DLS, and the level of the lower surface of the dam insulating pattern LDS may each refer to a level positioned at the lowest point among the lower surfaces.

The upper surface of the landing pad insulating pattern LS positioned in the cell region CR may be positioned at substantially the same level as the upper surface of the dummy insulating pattern DLS positioned in the dummy region IR and the upper surface of the dam insulating pattern LDS. However, embodiments are not limited thereto, and at least one of the landing pad insulating pattern LS positioned in the cell region CR, the dummy insulating pattern DLS positioned in the dummy region IR, and the dam insulating pattern LDS may contain a different material, or at least one may be positioned at a different level.

The semiconductor device 10 according to an embodiment may further include a plurality of dummy capacitors DCAP positioned in the dummy region IR.

Although not illustrated in detail in FIGS. 4 and 5, the plurality of dummy capacitors DCAP may be arranged in a matrix pattern in the first direction X and the second direction Y substantially the same as the plurality of capacitors CAP described above with reference to FIG. 3.

The planar arrangement and planar shape of each of the plurality of dummy capacitors DCAP may be substantially the same to the planar arrangement and planar shape of the plurality of capacitors CAP described above with reference to FIG. 3.

The plurality of dummy capacitors DCAP may be positioned respectively on the plurality of dummy landing pads DLP. The plurality of dummy capacitors DCAP may be entirely or partially overlapped each of the plurality of dummy landing pads DLP in the third direction Z.

The dummy capacitor DCAP may include a first dummy electrode 210b, a second dummy electrode 230b, and a dummy dielectric film 220b positioned between the first dummy electrode 210b and the second dummy electrode 230b.

The first dummy electrode 210b may be positioned on the dummy landing pad DLP. The first dummy electrode 210b may extend in the third direction Z on the dummy landing pad DLP.

The first dummy electrode 210b positioned in the dummy region IR may be formed together with the first electrode 210a of the capacitor CAP positioned in the cell region CR using the same material in the same process.

Accordingly, the first dummy electrode 210b positioned in the dummy region IR contain the same material as the first electrode 210a of the capacitor CAP positioned in the cell region CR, and may be positioned at substantially the same level as the first electrode 210a.

The dummy dielectric film 220b may extend conformally along the upper surface and side profile of the first dummy electrode 210b. That is, the dummy dielectric film 220b may cover the side surface and upper surface of the first dummy electrode 210b. The dummy dielectric film 220b may cover a portion of the upper surface of the dummy landing pad DLP and a portion of the upper surface of the dummy insulating pattern DLS in the dummy region IR.

The dummy dielectric film 220b may cover the upper surface of the dam structure DS and the upper surface of the dam insulating pattern LDS in the dummy region IR.

The dummy dielectric film 220b positioned in the dummy region IR may be formed together with the dielectric film 220a of the capacitor CAP positioned in the cell region CR using the same material at the same process.

Accordingly, the dummy dielectric film 220b positioned in the dummy region IR contains the same material as the dielectric film 220a of the capacitor CAP positioned in the cell region CR, and may be positioned at substantially the same level as the dielectric film 220a.

The second dummy electrode 230b may be positioned on the dummy dielectric film 220b. The second dummy electrode 230b may entirely cover the first dummy electrode 210b. That is, the second dummy electrode 230b may cover the upper surface and side surface of the first dummy electrode 210b.

The second dummy electrode 230b positioned in the dummy region IR may be formed together with the second electrode 230a of the capacitor CAP positioned in the cell region CR using the same material at the same process.

Accordingly, the second dummy electrode 230b positioned in the dummy region IR contains the same material as the second electrode 230a of the capacitor CAP positioned in the cell region CR, and may be positioned at substantially the same level as the second electrode 230a.

The semiconductor device 10 according to an embodiment may include the plurality of bit line pads BLP positioned spaced apart from each other in a first direction X in a peripheral circuit region PR.

The plurality of bit line pads BLP may be connected to one end portion of some of the plurality of bit line structures BLS in a peripheral circuit region PR.

Here, the peripheral circuit region PR may refer to a peripheral circuit region PR positioned on one side of the second direction Y of the cell region CR.

Specifically, as illustrated in FIGS. 4 and 5, the plurality of bit line pads BLP in the peripheral circuit region PR positioned on one side of the second direction Y of the cell region CR may be connected to one end portion BLS1_E of the first bit line structure BLS1.

Although not illustrated in detail in FIGS. 4 and 5, the plurality of bit line pads BLP may be arranged in the first direction X in the peripheral circuit region PR positioned on the other side of the second direction Y of the cell region CR, and the plurality of bit line pads BLP in the peripheral circuit region PR positioned on the other side of the second direction Y of the cell region CR may be connected to the other end portion of the second bit line structure BLS2.

In an embodiment, the planar area of the bit line pad BLP may be larger than the planar area of the bit line structure BLS. For example, a width of the bit line pad BLP in the first direction X may be greater than a width of the bit line structure BLS in the first direction X.

As such, since the planar area of the bit line pad BLP is greater than the planar area of the bit line structure BLS, when the bit line structure BLS in the peripheral circuit region PR is connected to a peripheral circuit wiring BP through the bit line pad BLP, a large contact area between the bit line pad BLP and the peripheral circuit wiring BP may be secured.

Through such a large contact area, the peripheral circuit wiring BP may be more stably formed on the bit line pad BLP during a process of forming the peripheral circuit wiring BP, thereby ensuring a sufficient process margin.

In an embodiment, the first buffer layer 112 and the second buffer layer 114 may extend from the cell region CR to the peripheral circuit region PR. The first buffer layer 112 and the second buffer layer 114 may be sequentially stacked on a substrate 110 positioned in the peripheral circuit region PR.

In an embodiment, the bit line pad BLP and the bit line structure BLS may be formed together in the same process step using the same conductive material.

Accordingly, a boundary between the bit line pad BLP and the bit line structure BLS may not be visually distinguishable.

For example, a boundary may not be recognized between the first bit line structure BLS1 connected to the bit line pad BLP and the bit line pad BLP in the peripheral circuit region PR. However, embodiments are not limited to the bit line pad BLP and the bit line structure BLS may be formed in separate process steps using different materials. In this case, a boundary may be recognized between the bit line pad BLP and the bit line structure BLS.

Specifically, in an embodiment, the bit line pad BLP may include a sequentially stacked first pad layer 132p, a second pad layer 145p, and a third pad layer 146p.

The first pad layer 132p contains the same material as the first bit line conductive layers 132a and 132b of the bit line structure BLS and may be positioned at substantially the same level.

The second pad layer 145p contains the same material as the second bit line conductive layers 145a and 145b of the bit line structure BLS and may be positioned at substantially the same level.

The third pad layer 146p contains the same material as the third bit line conductive layers 146a and 146b of the bit line structure BLS and may be positioned at substantially the same level. However, embodiments are not limited thereto, and any one of the first to third pad layers 132p, 145p, and 146p constituting the bit line pad BLP may be omitted, or a layer other than the first to third pad layers 132p, 145p, and 146p may be further included.

A description of the conductive materials contained in each of the first to third pad layers 132p, 145p, and 146p is omitted since the same or substantially the same applies to the materials of the first bit line conductive layers 132a and 132b, the second bit line conductive layers 145a and 145b, and the third bit line conductive layers 146a and 146b that constitute the above-described bit line structure BLS.

The semiconductor device 10 according to an embodiment may further include a pad capping pattern 148p positioned on a bit line pad BLP.

The pad capping pattern 148p and the bit line capping patterns 148a and 148b positioned on the bit line structure BLS may be formed together in the same process step using the same insulating material.

Accordingly, the pad capping pattern 148p may contain the same material as the bit line capping patterns 148a and 148b and may be positioned at substantially the same level. However, embodiments are not limited thereto, and the pad capping pattern 148p and the bit line capping patterns 148a and 148b may contain different materials or be positioned at different levels.

A description of the insulating material contained in the pad capping pattern 148p is omitted for conciseness since the same or substantially the same applies to the materials of the above-described bit line capping patterns 148a and 148b.

The semiconductor device 10 according to an embodiment may include the plurality of peripheral circuit wirings BP each connected to the plurality of bit line pads BLP in a peripheral circuit region PR.

The semiconductor device 10 according to an embodiment may further include a peripheral circuit contact BPC connecting the peripheral circuit wiring BP and the bit line pad BLP and a peripheral circuit capping layer 250 covering the peripheral circuit wiring BP.

The plurality of peripheral circuit wirings BP positioned in the peripheral circuit region PR may overlap each of the bit line pads BLP in the third direction Z.

A width of the peripheral circuit wiring BP in the first direction X may be different from a width of the bit line pad BLP in the first direction X. For example, the width of the peripheral circuit wiring BP in the first direction X may be smaller than the width of the bit line pad BLP in the first direction X. However, the relationship between the width of the peripheral circuit wiring BP and the width of the bit line pad BLP is not limited to these relationships and may be variously changed.

The peripheral circuit wiring BP may be positioned on the pad capping pattern 148p. The peripheral circuit wiring BP may be connected to the bit line pad BLP through a peripheral circuit contact BPC penetrating at least a portion of a pad capping pattern 148p and the bit line pad BLP.

As illustrated in FIG. 7, in an embodiment, the peripheral circuit contact BPC may be connected to the second pad layer 145p of the bit line pad BLP by penetrating the pad capping pattern 148p and the third pad layer 146p of the bit line pad BLP. The peripheral circuit contact BPC may be connected to the upper surface of the second pad layer 145p of the bit line pad BLP.

Accordingly, a side surface of the peripheral circuit contact BPC may be surrounded by the pad capping pattern 148p and the third pad layer 146p of the bit line pad BLP. However, the connection relationship between the peripheral circuit contact BPC and the bit line pad BLP is not limited to this connection relationship and may be variously changed. For example, the peripheral circuit contact BPC may penetrate the first to third pad layers 132p, 145p, and 146p of the bit line pad BLP.

As another example, the peripheral circuit contact BPC may be connected to an upper surface of a first pad layer 132p by sequentially penetrating the third pad layer 146p and the second pad layer 145p of a bit line pad BLP.

The peripheral circuit capping layer 250 may contain an insulating material. For example, the peripheral circuit capping layer 250 may contain silicon oxide, silicon nitride, silicon oxynitride, or a combination thereof. However, the material of the peripheral circuit capping layer 250 is not limited to these materials and may be variously changed.

According to the semiconductor device 10 according to an embodiment, the plurality of dam structures DS overlapping end portions of the plurality of bit line structures BLS in a dummy region IR may be positioned spaced apart from each in an island pattern in a plan view.

Accordingly, during a process of forming the spacer structures BS1 and BS2 surrounding each of the adjacent bit line structures BLS, even if a portion of the first and second spacer structures BS1 and BS2 is removed and bit lines included in the end portions of the adjacent bit line structures BLS are partially exposed, a short may be prevented by preventing the exposed bit lines from being directly connected through the dam structures DS, since the plurality of dam structures DS are spaced apart from each other.

During a process of forming the spacer structures BS1 and BS2, even if a portion of the first and second spacer structures BS1 and BS2 is removed and a leakage current occurs due to a reduced distance between a bit line included in the bit line structure BLS and a dam structure DS, a short may still be prevented because the plurality of dam structures DS are arranged to be spaced apart from each other, thereby preventing the bit lines from being electrically connected to each other through the dam structures DS.

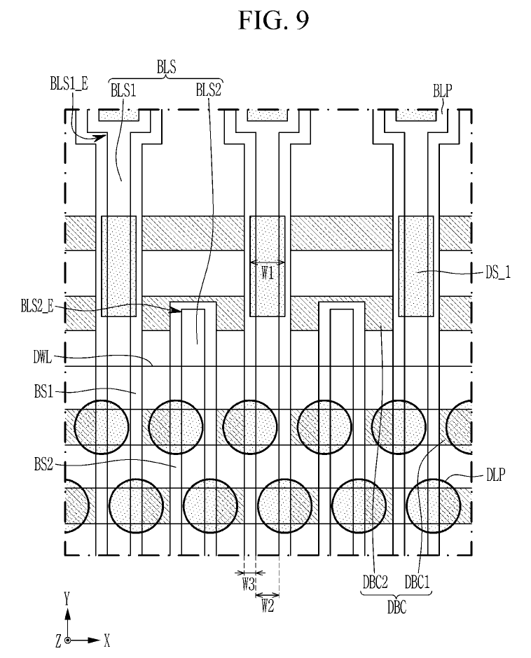

Hereinafter, semiconductor devices according to various embodiments will be described with reference to FIGS. 9 to 16. In the following examples, the same components as those in the previously described examples are referred to by the same reference numerals, and duplicate descriptions are omitted or simplified for conciseness, with a focus on differences.

FIGS. 9 to 16 are enlarged plan views illustrating portions of semiconductor devices according to some embodiments.

Specifically, FIGS. 9 to 16 are enlarged views illustrating portions of the dummy region IR and the peripheral circuit region PR of a semiconductor device according to some embodiments.

According to the semiconductor device according to the embodiment illustrated in FIG. 9, there is a difference from the semiconductor device 10 according to the embodiment illustrated in FIG. 4 in that the arrangement of a plurality of dam structures DS_1 is different from the plurality of dam structures DS in FIG. 4.

Referring to FIG. 9, the plurality of dam structures DS_1 may be arranged to overlap some of the bit line structures BLS among the plurality of bit line structures BLS, in the third direction Z, respectively, in the dummy region IR.

Here, the dummy region IR may refer to a dummy region IR positioned on one side of the second direction Y.

Specifically, the plurality of dam structures DS_1 may be positioned to overlap respectively the plurality of first bit line structures BLS1 among the plurality of bit line structures BLS positioned in the dummy region IR in the third direction Z, and may be positioned not to overlap the plurality of second bit line structures BLS2 in the third direction Z.

In the embodiment illustrated in FIG. 9, the plurality of dam structures DS_1 may be non-overlapping with the end portions BLS2_E of the plurality of second bit line structures BLS2 in the third direction Z.

In the embodiment illustrated in FIG. 9, each of the plurality of dam structures DS_1 may overlap, in the third direction Z, at least a portion of a corresponding first bit line structure BLS1 that extends in the second direction Y between adjacent second dummy storage contacts DBC2.

Each of plurality of dam structures DS_1 may overlap, in a third direction Z, an extension portion of the corresponding first bit line structure BLS1 that is directly connected to an end portion BLS1_E of the first bit line structure BLS1.

The plurality of dam structures DS_1 may be spaced apart from each other in the first direction X with the plurality of second dummy storage contacts DBC2 interposed therebetween.

The plurality of dam structures DS_1 may be positioned spaced apart in the first direction X with the second bit line structure BLS2 therebetween. An end portion BLS2_E of the second bit line structure BLS2 may be positioned between dam structures DS_1 spaced apart in the first direction X.

Each of the plurality of dam structures DS_1 may be positioned so as to be non-overlapping the plurality of second dummy storage contacts DBC2 in the third direction Z. However, the arrangement of the plurality of dam structures DS_1 is not limited to this arrangement and may be variously changed. For example, unlike the example shown in FIG. 9, the center of each of the plurality of dam structures DS_1 may be shifted from the center of the first bit line structure BLS1 toward one side or the other in the first direction X, and may overlap, in the third direction Z, a portion of each of the plurality of second dummy storage contacts DBC2 that are positioned on either side of the dam structure DS_1 in the first direction X.

In the embodiment illustrated in FIG. 9, each of the plurality of dam structures DS_1 may be a rectangular shape in a plan view, extending in the second direction Y between adjacent second dummy storage contacts DBC2, and having a short axis in the first direction X and a long axis in the second direction Y in a plan view. However, the planar shape of the dam structure DS_1 is not limited to this shape and may be variously changed. For example, the dam structure DS_1 may have a shape in which corners in a plan view have rounded.

Each of the plurality of dam structures DS_1 may overlap, in the third direction Z, first spacer structures BS1 that are positioned on both sides of the first bit line structure BLS1 extending in the second direction Y between adjacent second dummy storage contacts DBC2.

In the embodiment illustrated in FIG. 9, the dam structure DS_1 may entirely overlap the first bit line structure BLS1 in the third direction Z, and may overlap a portion of each of the first spacer structures BS1 positioned on both sides of the first bit line structure BLS1 in the third direction Z. However, the overlapping relationship between the dam structure DS_1 and the first bit line structure BLS1 and the overlapping relationship between the dam structure DS_1 and the first spacer structure BS1 may be variously changed. For example, the dam structure DS_1 may overlap a portion of the first bit line structure BLS1 in the third direction Z, and may entirely overlap one of the first spacer structures BS1 positioned on both sides of the first bit line structure BLS1 in the third direction Z.

In the embodiment illustrated in FIG. 9, a width of the dam structure DS_1 in the first direction X may be smaller than the sum of the width of the first bit line structure BLS1 in the first direction X and the widths of each of the first spacer structures BS1 positioned on both sides of the first bit line structure BLS1.

Specifically, the dam structure DS_1 has a first width W1 in the first direction X, the first bit line structure BLS1 has a second width W2 in the first direction X, and each of the first spacer structures BS1 positioned on both sides of the first bit line structure BLS1 may have a third width W3 in the first direction X.

Here, each of the first width W1, the second width W2, and the third width W3 may refer to a maximum width in the first direction X.

In the embodiment illustrated in FIG. 9, the first width W1 may be larger than each of the second width W2 and the third width W3. The first width W1 may be smaller than the sum of the second width W2 and the plurality of third widths W3. However, the relationship between the first width W1, the second width W2, and the third width W3 is not limited to these relationships and may be variously changed.

Accordingly, the dam structure DS_1 may be positioned so as not to overlap each of the second dummy storage contacts DBC2 positioned on both sides of the first direction X of the dam structure DS_1 in the third direction Z. For example, the dam structure DS_1 may be positioned on the first bit line structure BLS1 so as not to overlap the second dummy storage contacts DBC2 positioned on both sides of the first direction X of the dam structure DS_1.

According to the semiconductor device of the present embodiment, the plurality of dam structures DS_1 positioned in the dummy region IR are spaced apart from each other and arranged in an island pattern in a plan view, and may not overlap end portions of the respective bit line structures BLS positioned in the dummy region IR, thereby achieving substantially the same effect as described in the above embodiment.

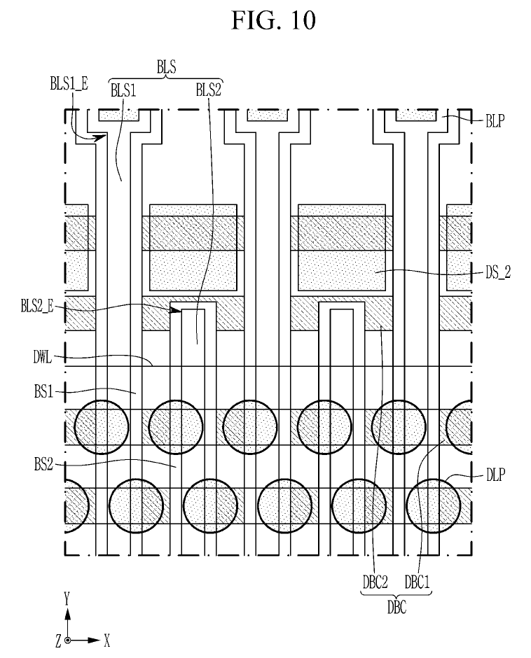

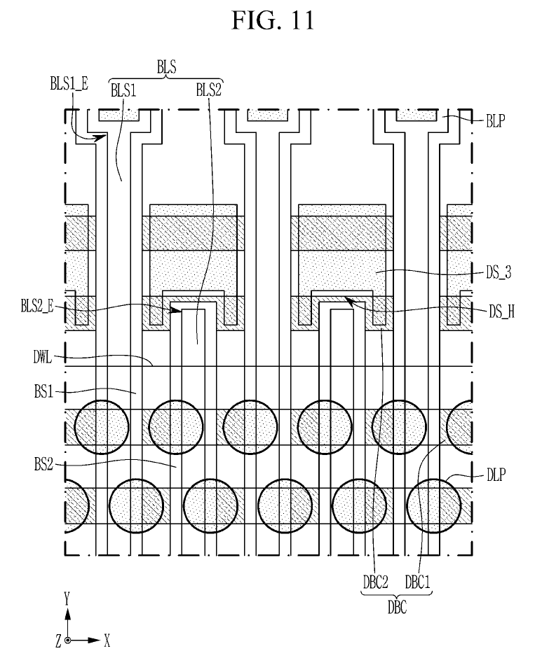

According to the embodiments illustrated in FIGS. 10 and 11, unlike the semiconductor device 10 according to the embodiment illustrated in FIG. 4, there is a difference in that dam structures DS_2 and DS_3 do not overlap the end portion BLS2_E of the second bit line structure BLS2 positioned in the dummy region IR.

According to the embodiments illustrated in FIGS. 10 and 11, the dam structures DS_2 and DS_3 may be positioned between adjacent bit line structures BLS positioned in the dummy region IR, substantially in the same manner as the plurality of dam structures DS according to the embodiment illustrated in FIG. 4.

According to the embodiments illustrated in FIGS. 10 and 11, the dam structures DS_2 and DS_3 may be non-overlapping each of the plurality of bit line structures BLS positioned in the dummy region IR in the third direction Z.

Here, the dummy region IR may refer to the dummy region IR positioned on one side of the second direction Y.

Referring first to FIG. 10, each of the plurality of dam structures DS_2 may be positioned between adjacent first bit line structures BLS1 in the dummy region IR, and may be positioned so as not to overlap, in the third direction Z, the second bit line structure BLS2 positioned between the adjacent first bit line structures BLS1.

Accordingly, each of the plurality of dam structures DS_2 may be positioned so as not to overlap, in a third direction Z, the plurality of first bit line structures BLS1 and the plurality of second bit line structures BLS2 positioned in the dummy region IR.

In the embodiment illustrated in FIG. 10, each of the plurality of dam structures DS_2 may overlap, in the third direction Z, with some of the plurality of second dummy storage contacts DBC2 that are positioned between the first bit line structures BLS1 in the dummy region IR.

Specifically, the dam structure DS_2 may not overlap, in the third direction Z, with the second dummy storage contact DBC2 that surrounds an end portion BLS2_E of the second bit line structure BLS2 among the plurality of second dummy storage contacts DBC2 positioned between the first bit line structures BLS1, and may overlap, in the third direction Z, with the remaining second dummy storage contacts DBC2 positioned between the first bit line structures BLS1.

However, the arrangement of the dam structure DS_2 is not limited to this arrangement.

In some embodiments, unlike the example illustrated in FIG. 10, the dam structure DS_2 may not overlap, in the third direction Z, with each of the plurality of second dummy storage contacts DBC2 that are positioned between adjacent first bit line structures BLS1 in the first direction X.

That is, the dam structure DS_2 may be positioned between second dummy storage contacts DBC2 that are spaced apart from each other in the second direction Y, between adjacent first bit line structures BLS1 in a plan view.

Referring to FIG. 11, each of the plurality of dam structures DS_3 may be positioned between adjacent first bit line structures BLS1 in the dummy region IR, and may not overlap, in the third direction Z, the second bit line structure BLS2 by including a groove DS_H that surrounds an end portion BLS2_E of the second bit line structure BLS2 in a plan view.

Accordingly, each of the plurality of dam structures DS_2 may be positioned so as not to overlap, in the third direction Z, the plurality of first bit line structures BLS1 and the plurality of second bit line structures BLS2 positioned in the dummy region IR.

Specifically, in the embodiment illustrated in FIG. 11, the groove DS_H of the dam structure DS_3 may be defined by the inner wall of the dam structure DS_3 adjacent to the end portion BLS2_E of the second bit line structure BLS2.

An inner wall of the dam structure DS_3 defining a groove DS_H of the dam structure DS_3 may surround an end BLS2_E of a second bit line structure BLS2 in a planar manner and a second spacer structure BS2 adjacent to the end BLS2_E of the second bit line structure BLS2.

Accordingly, the groove DS_H of the dam structure DS_3 may surround the end portion BLS2_E of the second bit line structure BLS2 and the second spacer structure BS2 adjacent thereto in a plan view.

In the embodiment illustrated in FIG. 11, a width of the groove DS_H of the dam structure DS_3 in the first direction X may be greater than the sum of a width of the second bit line structure BLS2 in the first direction X and the widths of each of the second spacer structures BS2 positioned on both sides of the second bit line structure BLS2 in the first direction X.

Accordingly, a portion of the dam structure DS_3 that defines the groove DS_H may be positioned so as not to overlap, in the third direction Z, the end portion BLS2_E of the second bit line structure BLS2 and an adjacent second spacer structure BS2.

Unlike as illustrated in FIG. 11, in some embodiments, the width of the groove DS_H of the dam structure DS_3 in the first direction X may be smaller than the sum of the width of the second bit line structure BLS2 in the first direction X and the widths of each of the second spacer structures BS2 positioned on both sides of the second bit line structure BLS2 in the first direction X.

Specifically, a portion defining the groove DS_H among the dam structures DS_3 may not overlap the end portion BLS2_E of the second bit line structure BLS2 in the third direction Z, and may overlap at least a portion of the second spacer structure BS2 adjacent to the end portion BLS2_E of the second bit line structure BLS2 in the third direction Z.

Accordingly, the dam structure DS_3 may overlap the second spacer structure BS2 adjacent to the end portion BLS2_E of the second bit line structure BLS2 in the third direction Z, does not overlap the second bit line structure BLS2 in the third direction Z, and may surround the end portion BLS2_E of the second bit line structure BLS2 in a plan view.

According to the semiconductor devices illustrated in FIGS. 10 and 11, the dam structures DS_2 and DS_3 are positioned so as not to overlap the plurality of bit line structures BLS positioned in the dummy region IR, thereby achieving substantially the same effect as described in the above embodiment.

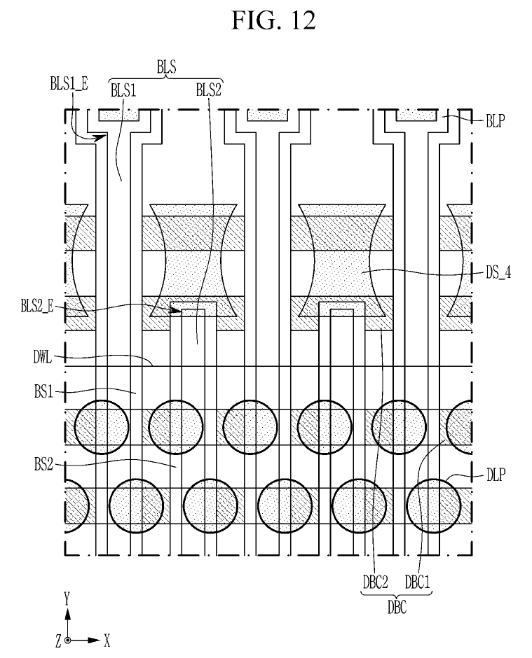

According to the semiconductor device according to the embodiment illustrated in FIG. 12, there is a difference from the semiconductor device 10 according to the embodiment illustrated in FIG. 4 in that a planar shape of a dam structure DS_4 is different.

Referring to FIG. 12, both side surfaces DS_S of the dam structure DS_4 may include a curved surface in a plan view.

Specifically, each of the both side surfaces DS_S of the plurality of dam structures DS_4 may have a concave curved shape in plan view. The both side surfaces DS_S of the dam structure DS_4 facing each other in the first direction X in a plan view, and may have a curved shape that is recessed toward the center of the dam structure DS_4 in a plan view.

Accordingly, a width of each of the plurality of dam structures DS_4 in the first direction X may decrease toward a central portion from both end portions in the second direction Y in a plan view.

That is, the dam structure DS_4 may have a maximum width in the first direction X at both end portions in the second direction Y in a plan view, and a minimum width in the first direction X at the center portion.

In the embodiment illustrated in FIG. 12, both side surfaces DS_S of the dam structure DS_4 facing each other in the first direction X in a plan view have the concave curved shape, and both side surfaces of the dam structure DS_4 facing each other in the second direction Y in a plan view have a straight shape, but the embodiments are not limited thereto. For example, unlike as illustrated in FIG. 12, in some embodiments, both side surfaces DS_S of the dam structure DS_4 facing each other in the first direction X and both side surfaces of the dam structure DS_4 facing each other in the second direction Y may have a concave curved shape in a plan view.

In some embodiments, each of the dam structures DS_1, DS_2, and DS_3 according to the embodiments shown in FIGS. 9 to 11 may have a curved shape in which both side surfaces in the first direction X are recessed toward a central portion in a plan view, substantially the same to the dam structure DS_4 according to the embodiment illustrated in FIG. 12.

According to the semiconductor device according to the embodiment illustrated in FIG. 12, it may have substantially the same effect as the semiconductor device 10 according to the above embodiments described with respect to FIGS. 1-8. According to the embodiment illustrated in FIG. 12, since each of the two side surfaces DS_S of the plurality of dam structures DS_4 has the concave curved shape in a plan view, adjacent dam structures DS_4 may be effectively prevented from being connected to each other.

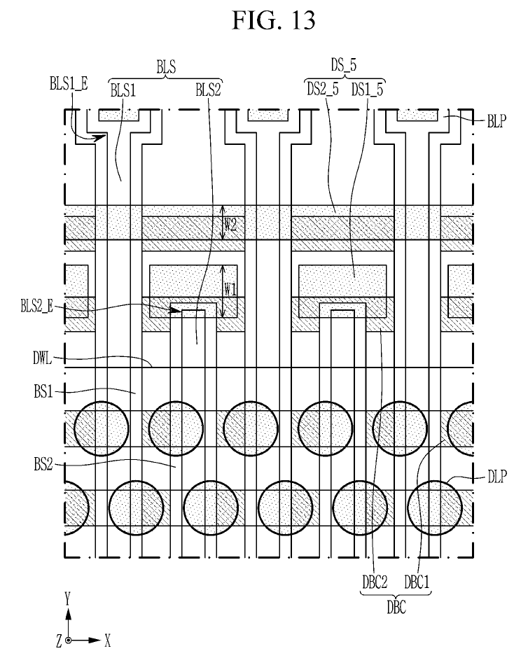

According to the embodiment illustrated in FIG. 13, unlike the semiconductor device 10 shown in FIG. 4, a plurality of dam structures DS_5 having different shapes in a plan view are spaced apart from each other and arranged in the dummy region IR.

Referring to FIG. 13, the plurality of dam structures DS_5 may be positioned between adjacent bit line structures BLS in the dummy region IR, and may include a plurality of first dam structures DS1_5, which are arranged in an island pattern in a plan view, and a second dam structure DS2_5, which extends in the first direction X to overlap the plurality of bit line structures BLS in the dummy region IR and has a line shape in a plan view.

Specifically, the plurality of first dam structures DS1_5 are positioned between adjacent first bit line structures BLS1 positioned in the dummy region IR, and may be arranged the island pattern in a plan view so as to overlap each end portion BLS2_E of the plurality of second bit line structures BLS2 positioned between adjacent first bit line structures BLS1 in the third direction Z.

The plurality of first dam structures DS1_5 may be positioned spaced apart in the first direction X with the first bit line structure BLS1 interposed therebetween. The plurality of first dam structures DS1_5 may overlap the end portion BLS2_E of the second bit line structure BLS2 in a plan view and the second spacer structure BS2 surrounding the end portion BLS2_E of the second bit line structure BLS2 in the third direction Z.

Each of the plurality of first dam structures DS1_5 may overlap, in the third direction Z, the second dummy storage contact DBC2 that surrounds the end portion BLS2_E of the second bit line structure BLS2 in a plan view among the plurality of second dummy storage contacts DBC2 spaced apart from each other in the second direction Y between adjacent first bit line structures BLS1.

Each of the plurality of first dam structures DS1_5 may not overlap, in the third direction Z, the remaining second dummy storage contacts DBC2.

The second dam structure DS2_5 extends in the first direction X to overlap the plurality of first bit line structures BLS1 spaced apart in the first direction X in the dummy region IR, and may have the line shape in a plan view.

The second dam structure DS2_5 may be non-overlapping the end portion BLS2_E of each of the plurality of second bit line structures BLS2 positioned in the dummy region IR in the third direction Z.

In the embodiment illustrated in FIG. 13, the second dam structure DS2_5 may not overlap, in the third direction Z, the end portion BLS2_E of the second bit line structure BLS2, which is subject to relatively greater etching during the formation of the spacer structures BS1 and BS2, but may overlap, in the third direction Z, extension portions of the plurality of first bit line structures BLS1, which are subject to relatively less etching.

Accordingly, although the second dam structure DS2_5 overlaps the extension portions of the adjacent first bit line structures BLS1, the first bit line structures BLS1 may not be connected to each other through the second dam structure DS2_5, which has the line shape in a plan view.

That is, a short circuit may not occur between the plurality of adjacent first bit line structures BLS1 due to the second dam structure DS2_5 having the line shape in a plan view.

In the embodiment illustrated in FIG. 13, it is illustrated that one second dam structure DS2_5 is positioned in the dummy region IR, but the number of second dam structures DS2_5 positioned in the dummy region IR is not limited thereto and may be variously changed. For example, a plurality of second dam structures DS2_5 spaced apart in the second direction Y may be positioned in the dummy region IR.

In the embodiment illustrated in FIG. 13, the first dam structure DS1_5 may have a first width W1 in the second direction Y in a plan view, and the second dam structure DS2_5 may have a second width W2 in the second direction Y in a plan view.

For example, the first width W1 may be larger than the second width W2.

As such, when the first width W1 is greater than the second width W2, it is possible to form various patterns having island pattern and line shapes in a plan view in the dummy region IR, while minimizing empty spaces between adjacent first bit line structures BLS1.

Accordingly, the process complexity caused by a pattern density difference between the cell region (see “CR” in FIG. 3) and the peripheral circuit region (see “PR” in FIG. 4) can be effectively reduced.

However, the relationship between the first width W1 and the second width W2 is not limited to this relationship and may be variously changed. For example, the first width W1 may be substantially the same to the second width W2, or the first width W1 may be smaller than the second width W2.

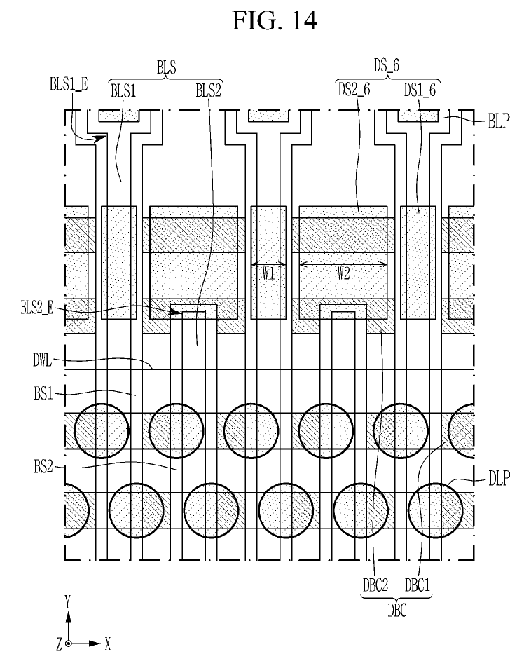

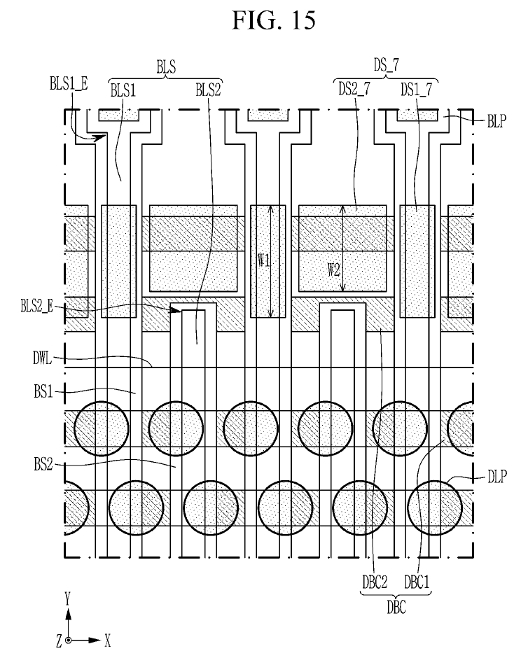

According to the embodiments shown in FIGS. 14 and 15, unlike the semiconductor device 10 of the embodiment shown in FIG. 4, a plurality of dam structures DS_6 and DS_7 having different areas in a plan view are spaced apart from each other and arranged in the dummy region IR.

First, referring to FIG. 14, the plurality of dam structures DS_6 positioned in the dummy region IR may include a first dam structure DS1_6 and a second dam structure DS2_6 having different widths in the first direction X.

Specifically, in the embodiment illustrated in FIG. 14, the plurality of dam structures DS_6 may include first dam structures DS1_6, each overlapping a corresponding first bit line structure BLS1 in the dummy region IR in the third direction Z.

The dam structures DS_6 may further include the plurality of second dam structures DS2_6 positioned between adjacent first bit line structures BLS1 in the dummy region IR, and overlapping, in the third direction Z, end portions BLS2_E of the plurality of second bit line structures BLS2 positioned between the adjacent first bit line structures BLS1.

The plurality of first dam structures DS1_6 and the plurality of second dam structures DS2_6 may be spaced apart from each other in the first direction X and arranged in an island pattern in a plan view.

The first dam structure DS1_6 and the second dam structure DS2_6 may be arranged alternately in the first direction X.

In the embodiment illustrated in FIG. 14, the plurality of first dam structures DS1_6 and the plurality of second dam structures DS2_6 may be spaced apart from each other in the first direction X such that their respective centers are substantially aligned on the same boundary in a plan view.

In the embodiment illustrated in FIG. 14, one side surface of each of the plurality of first dam structures DS1_6 in the second direction Y may be substantially aligned with one side surface of each of the plurality of second dam structures DS2_6 in the second direction Y, and the opposite side surface of each of the plurality of first dam structures DS1_6 in the second direction Y may be substantially aligned with the opposite side surface of the second dam structures DS2_7 in the second direction Y.

In the embodiment illustrated in FIG. 14, the first dam structure DS1_6 may have a first width W1 in the first direction X, and the second dam structure DS2_6 may have a second width W2 in the first direction X.

Here, each of the first width W1 and the second width W2 may refer to a maximum width in the first direction X.

In the embodiment illustrated in FIG. 14, the first width W1 may be different from the second width W2. For example, the first width W1 may be smaller than the second width W2. That is, the width in the first direction X of the first dam structure DS1_6 may be smaller than the width in the first direction X of the second dam structure DS2_6. However, the relationship between the first width W1 and the second width W2 is not limited to these relationships and may be variously changed.

In the embodiment illustrated in FIG. 14, the width of the first dam structure DS1_6 in the second direction Y may be substantially the same as the width of the second dam structure DS2_6 in the second direction Y.

In the embodiment illustrated in FIG. 14, the first dam structure DS1_6 may be substantially the same to the dam structure DS_1 according to the embodiment according to FIG. 9, and the second dam structure DS2_6 may be substantially the same to the dam structure DS according to the embodiment illustrated in FIG. 5.

Accordingly, the description of the dam structure DS_1 according to the embodiment shown in FIG. 9 may be substantially the same as that of the first dam structure DS1_6 of the embodiment illustrated in FIG. 14, and the description of the dam structure DS according to the embodiment shown in FIG. 5 may be substantially the same as that of the second dam structure DS2_6.

Thus, detailed descriptions thereof will be omitted for conciseness.

According to the embodiment illustrated in FIG. 15, unlike the embodiment illustrated in FIG. 14, a plurality of dam structures DS_7 positioned in the dummy region IR may include first dam structures DS1_7 and second dam structures DS2_7 having different widths in the first direction X and the second direction Y.

Specifically, referring to FIG. 15, the plurality of dam structures DS_7 may include the plurality of first dam structures DS1_7, each of which overlaps, in the third direction Z, a corresponding one of the plurality of first bit line structures BLS1 in the dummy region IR.

The plurality of dam structures DS_7 may further include the plurality of second dam structures DS2_7, each of which is positioned between adjacent first bit line structures BLS1 and does not overlap, in the third direction Z, an end portion BLS2_E of the second bit line structure BLS2 positioned therebetween.

The plurality of first dam structures DS1_7 and the plurality of second dam structures DS2_7 may be spaced apart from each other in the first direction X and may be arranged in an island pattern in a plan view.

The first dam structure DS1_7 and the second dam structure DS2_7 may be arranged alternately in the first direction X.

In the embodiment illustrated in FIG. 15, the plurality of first dam structures DS1_7 and the plurality of second dam structures DS2_7 may be spaced apart from each other in the first direction X such that their respective centers are substantially aligned with the same boundary in a plan view.

In the embodiment illustrated in FIG. 15, a side surface of each of the plurality of first dam structures DS1_7 positioned on one side in the second direction Y may be substantially aligned with a side surface of each of the plurality of second dam structures DS2_7 positioned on the same side in the second direction Y.

The opposite side surface of each of the first dam structures DS1_7 in the second direction Y may also be substantially aligned with the corresponding opposite side surface of each of the second dam structures DS2_7.

In the embodiment illustrated in FIG. 15, the first dam structure DS1_7 may have a first width W1 in the second direction Y and the second dam structure DS2_7 may have a second width W2 in the first direction X.

Here, each of the first width W1 and the second width W2 may refer to a maximum width in the second direction Y.

In the embodiment illustrated in FIG. 15, the first width W1 may be different from the second width W2. For example, the first width W1 may be larger than the second width W2. That is, the width of the first dam structure DS1_7 in the second direction Y may be greater than the width of the second dam structure DS2_7 in the second direction Y. However, the relationship between the first width W1 and the second width W2 is not limited to these relationships and may be variously changed.

As described above, since the second width W2 of the second dam structure DS2_7 is smaller than the first width W1 of the first dam structure DS1_7, the second dam structure DS2_7 may be positioned so as not to overlap the end portion BLS2_E of the second bit line structure BLS2 positioned between the adjacent first bit line structures BLS1 in the third direction Z.

In the embodiment illustrated in FIG. 15, the width of the first dam structure DS1_7 in the first direction X may be different from the width of the second dam structure DS2_7 in the first direction X. For example, the width of the first dam structure DS1_7 in the first direction X may be smaller than the width of the second dam structure DS2_7 in the first direction X. However, the relationship between the widths of each of the first dam structure DS1_7 and the second dam structure DS2_7 in the first direction X is not limited thereto and may be variously changed.

In the embodiment illustrated in FIG. 14, the first dam structure DS1_7 may be substantially the same to the dam structure DS_1 according to the embodiment according to FIG. 9, and the second dam structure DS2_6 may be substantially the same to the dam structure DS_2 according to the embodiment illustrated in FIG. 10.

Accordingly, the description of the dam structure DS_1 according to the embodiment shown in FIG. 9 may be substantially equally applied to the first dam structures DS1_7 according to the embodiment illustrated in FIG. 15, and the description of the dam structure DS_2 according to the embodiment shown in FIG. 10 may be substantially equally applied to the second dam structures DS2_7 according to the embodiment illustrated in FIG. 15.

Thus, detailed descriptions of the first dam structures DS1_7 and the second dam structures DS2_7 will be omitted for conciseness.

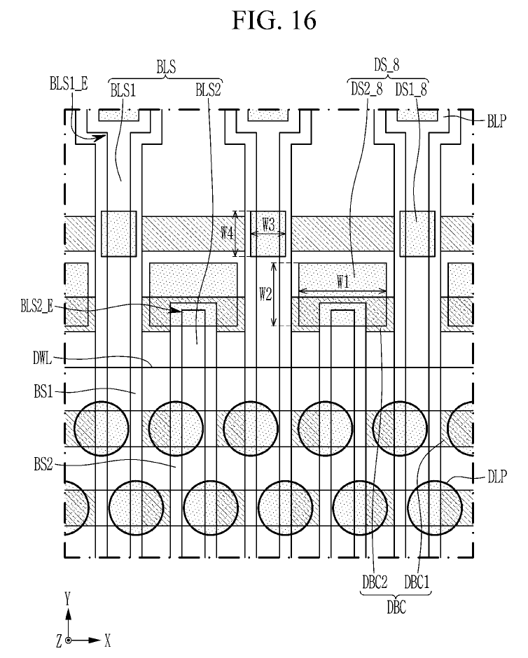

According to the embodiment shown in FIG. 16, unlike the semiconductor device 10 according to the embodiment shown in FIG. 4, a plurality of dam structures DS_8 having different planar areas and arranged in a zigzag pattern in a plan view in the dummy region IR.

In the embodiment illustrated in FIG. 16, the plurality of dam structures DS_8 positioned in the dummy region IR may include a first dam structure DS1_8 and a second dam structure DS2_8 having different planar areas.

Specifically, the plurality of dam structures DS_8 may include a plurality of first dam structures DS2_8 positioned between the first bit line structures BLS1 adjacent to each other in the dummy region IR, and overlapping each of the end portions BLS2_E of the plurality of second bit line structures BLS2 positioned between the first bit line structures BLS1 adjacent to each other in the third direction Z, and a plurality of second dam structures DS2_8 overlapping each of the plurality of first bit line structures BLS1 in the third direction Z in the dummy region IR.

Each of the plurality of first dam structures DS1_8 overlaps the second dummy storage contact DBC2 surrounding the end portion BLS2_E of the second bit line structure BLS2 in a plan view among the plurality of second dummy storage contacts DBC2 positioned spaced apart from each other in the second direction Y between adjacent first bit line structures BLS1 in the third direction Z, and may not overlap the remaining second dummy storage contacts DBC2 in the third direction Z. However, embodiments are not limited thereto, and the first dam structure DS1_8 may be positioned to overlap each of the plurality of second dummy storage contacts DBC2 positioned spaced apart from each other in the second direction Y between the adjacent first bit line structures BLS1 in the third direction Z.

The plurality of first dam structures DS1_8 and the plurality of second dam structures DS2_8 may be arranged in a zigzag pattern in the first direction X in a plan view. That is, the plurality of first dam structures DS1_8 and the plurality of second dam structures DS2_8 may be arranged alternately on one side and the other side of the second direction Y in the first direction X so as to be arranged in a zigzag pattern in a plan view.

In the embodiment illustrated in FIG. 16, the plurality of first dam structures DS1_8 and the plurality of second dam structures DS2_8 may be arranged in the zigzag pattern in the first direction X in a plan view.

Accordingly, the first dam structures DS1_8 may be aligned in the first direction X to form a first row, and the second dam structures DS2_8, spaced apart from the first dam structures DS1_8, may be aligned in the first direction X to form a second row.

Since the plurality of first dam structures DS1_8 and the plurality of second dam structures DS2_8 are arranged in the zigzag pattern in a plan view to form different rows in the first direction X, the first dam structures DS1_8 may be positioned not to overlap the second dam structures DS2_8 in the plan view.

However, the arrangement relationship between the first dam structure DS1_8 and the second dam structure DS2_8 is not limited to this arrangement. For example, at least a portion of each of the plurality of first dam structures DS1_8 may be arranged in a zigzag pattern so as to overlap the plurality of second dam structures DS2_8 in the second direction Y in a plan view.

In the embodiment illustrated in FIG. 16, the first dam structure DS1_8 may have a first width W1 in the first direction X and a second width W2 in the second direction Y.

The second dam structure DS2_8 may have a third width W3 in the first direction X and a fourth width W4 in the second direction Y.

Here, the first width W1 and the third width W3 may each refer to the maximum width in the first direction X, and the second width W2 and the fourth width W4 may each refer to the maximum width in the second direction Y.

In the embodiment illustrated in FIG. 16, the first width W1 may be different from the third width W3, and the second width W2 may be different from the fourth width W4. For example, the first width W1 may be larger than the third width W3, and the second width W2 may be larger than the fourth width W4.

Accordingly, the planar area of the first dam structure DS1_8 may be larger than the planar area of the second dam structure DS2_8. However, embodiments are not limited thereto, and as the relationship between the first width W1 and the third width W3 and/or the relationship between the second width W2 and the fourth width W4 are variously changed, the relationship between the planar area of the first dam structure DS1_8 and the planar area of the second dam structure DS2_8 may be variously changed. For example, the first width W1 may be substantially the same to the third width W3 or may be smaller than the third width W3. The second width W2 may be substantially the same to the fourth width W4, or the second width W2 may be smaller than the fourth width W4.

According to the semiconductor devices according to the embodiments illustrated in FIGS. 13 to 17, substantially the same effect as the semiconductor device 10 according to embodiments described above with respect to FIGS. 1-12 may be achieved.

By forming the plurality of dam structures having various shapes or different planar areas in the dummy region IR, or by varying the planar arrangement of the plurality of dam structures formed in the dummy region IR, it is possible to minimize empty spaces between the components positioned in the dummy region IR, or to minimize the pattern difference between the components in the dummy region IR and those in the cell region CR and the peripheral circuit region PR, thereby more effectively reducing process complexity caused by pattern density differences between the cell region CR and the peripheral circuit region PR.

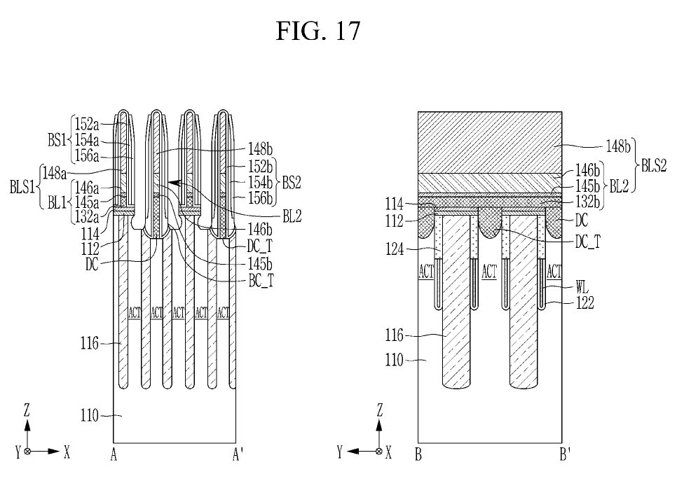

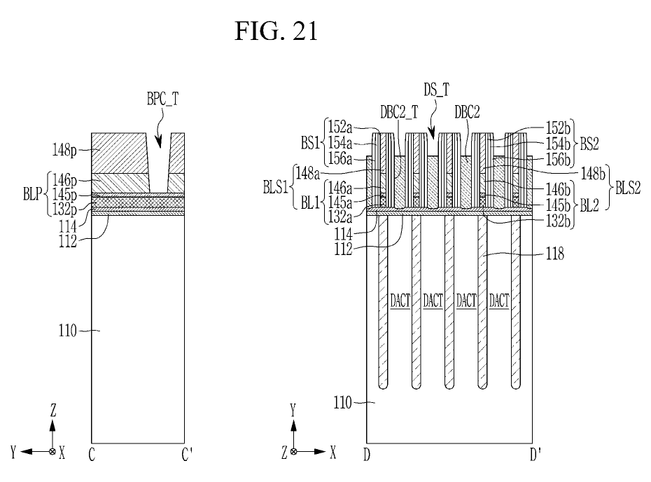

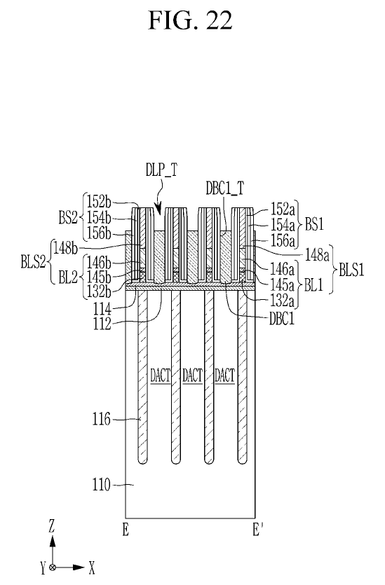

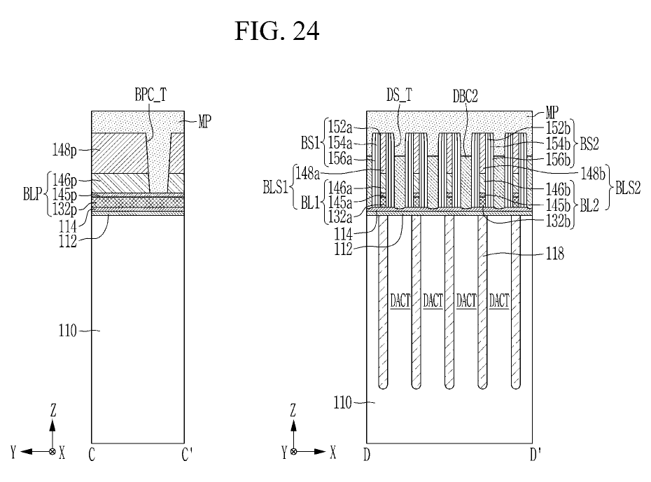

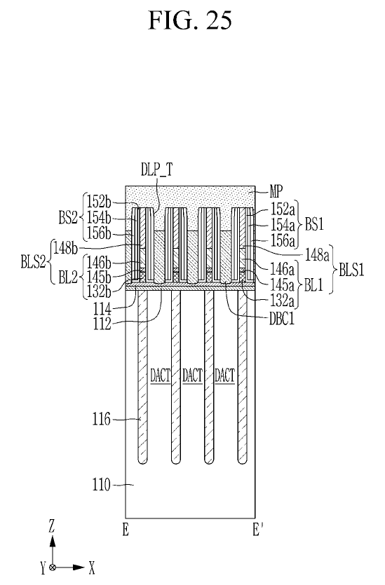

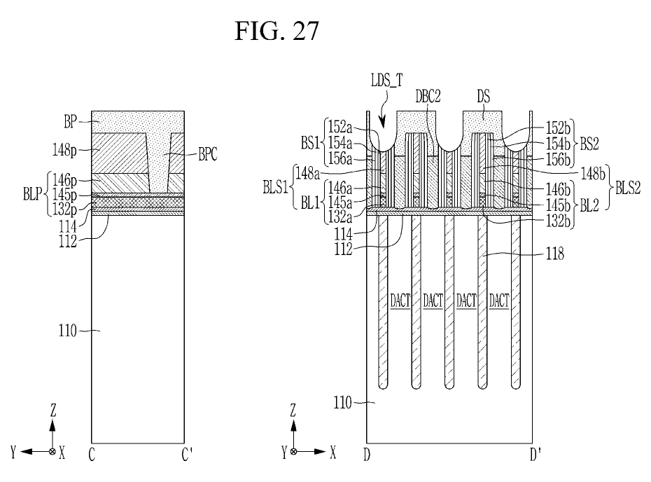

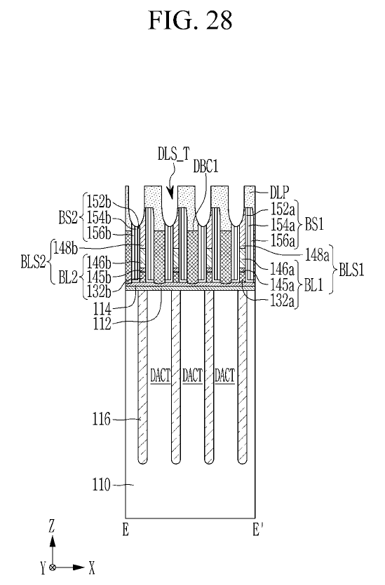

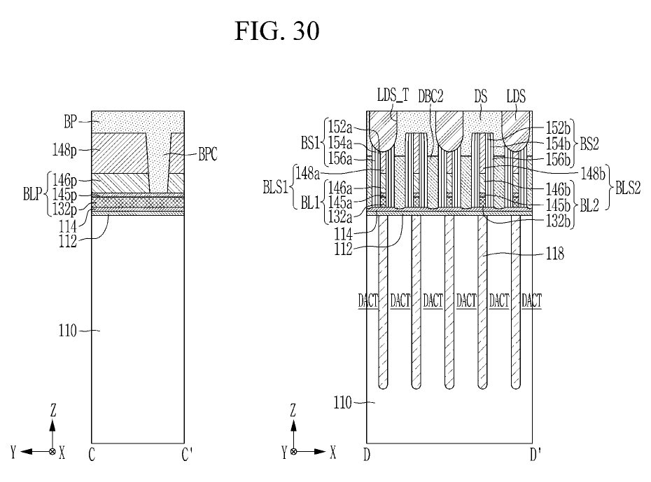

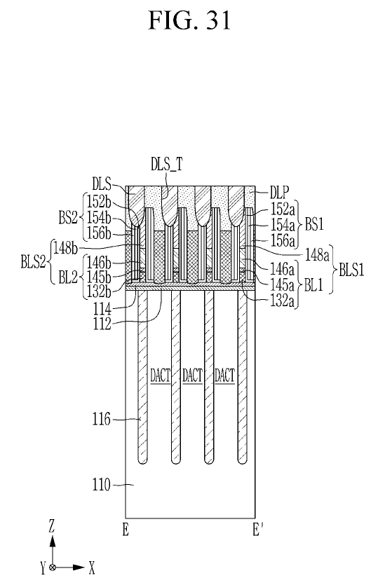

Hereinafter, a method for manufacturing a semiconductor device will be described with reference to FIGS. 17 to 31. Hereinafter, the same reference numerals will be used for the same configurations described previously, and duplicate descriptions will be omitted or simplified, with explanations focusing on the differences.

FIGS. 17 to 31 are drawings for explaining a method for manufacturing a semiconductor device according to an embodiment.

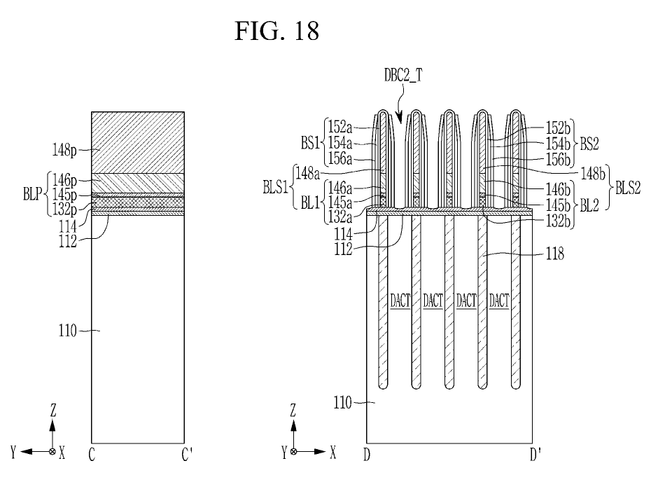

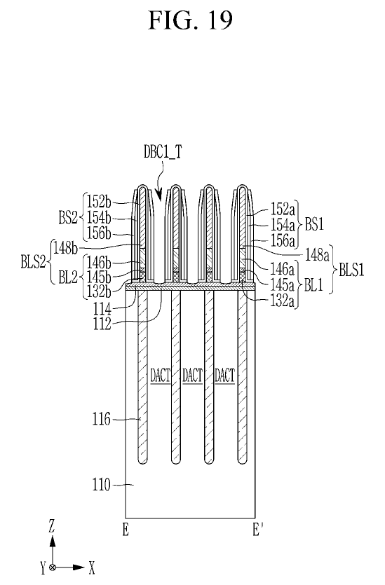

Specifically, FIGS. 17, 20, 23, 26, and 29 are cross-sectional views taken along lines A-A’ and B-B’ of FIG. 3 at each manufacturing process step to explain a method for manufacturing a semiconductor device according to an embodiment, and FIGS. 18, 21, 24, 27, and 30 are cross-sectional views taken along lines C-C’ and D-D’ of FIG. 4 at each manufacturing process step to explain a method for manufacturing a semiconductor device according to an embodiment, and FIGS. 19, 22, 25, 28, and 31 are cross-sectional views taken along lines E-E’ of FIG. 4 at each manufacturing process step to explain a method for manufacturing a semiconductor device according to an embodiment.

First, referring to FIGS. 17 to 19 with 3 and 4, the plurality of device isolation layers 116 and the plurality of dummy device isolation layers 118 defining the active region ACT and the dummy active region DACT in each of the cell region CR and the dummy region IR of the substrate 110 may be formed.

The step of forming an active region ACT and the dummy active region DACT may include a step of implanting impurity ions into regions of the substrate 110 corresponding to each of the active region ACT and the dummy active region DACT, in each of the cell region CR and the peripheral circuit region PR of the substrate 110.

In some embodiments, in the step of forming the device isolation layer 116 and the dummy device isolation layer 118 defining the active region ACT and the dummy active region DACT in each of the cell region CR and the dummy region IR of the substrate 110, a peripheral device isolation layer (not shown) defining a peripheral active region (not shown) in a peripheral circuit region PR of the substrate 110 may be formed together.

The step of forming the device isolation layer 116 and the dummy active device isolation layer 118 may include the step of patterning the substrate 110 to form a plurality of trenches, filling the plurality of trenches with an insulating material, and then and planarizing the result.

Subsequently, the cell region CR of a substrate 110 is patterned to form a plurality of word line trenches, and then the word line insulating pattern 122, the word line WL, and the word line capping layer 124 may be sequentially formed within the plurality of word line trenches.

Specifically, the word line insulating pattern 122 may be formed conformally along the inner wall of the word line trench.

Subsequently, the word line WL may be formed on the word line insulating pattern 122 so as to fill a remaining portion of the word line trench after formation of the word line insulating pattern 122.

In FIG. 17, the word line WL is illustrated as having a single-layer structure, but is not limited thereto, and the word line WL may have a multi-layer structure in which a plurality of conductive layers is stacked.

Subsequently, the word line capping layer 124 may be formed to completely fill the remaining area of the word line trench after formation of the word line insulating pattern 122 and the word line WL.

The step of forming the word line capping layer 124 may include a step of filling an insulating material for forming the word line insulating capping layer 124 in the word line trench, and then performing a planarization process on the insulating material.

Accordingly, the upper surface of the word line capping layer 124, the upper surface of the substrate 110, and the upper surface of the device isolation layer 116 may be substantially flat.

Although not illustrated in detail, in a process step of forming the plurality of word lines WL in the cell region CR of a substrate 110, the plurality of dummy word lines (see ‘DWL’ in FIG. 4) may be formed in the dummy region IR of the substrate 110. For example, after forming a plurality of dummy word line trenches by patterning the dummy region IR of the substrate 110, a dummy word line insulating pattern (not shown), the dummy word line DWL, and a dummy word line capping layer (not shown) may be sequentially formed in the plurality of dummy word line trenches.

In an embodiment, the method may further include a step of forming a source region and a drain region in the plurality of active regions ACT by implanting impurity ions into active regions ACT positioned on both sides of the plurality of word lines WL before or after forming the plurality of word lines WL.

Subsequently, the first buffer layer 112 and the second buffer layer 114 may be sequentially formed using different insulating materials on the surface of the substrate 110. Since the first buffer layer 112 and the second buffer layer 114 contain different materials, they may have different etching selectivities.

Subsequently, a bit line contact trench DC_T may be formed that penetrates the buffer layers 112 and 114 in the cell region CR of the substrate 110 and exposes the active region ACT.

The bit line contact trench DC_T may recess a portion of the active region ACT and a portion of the device isolation layer 116. Also, the bit line contact trench DC_T may recess a portion of the word line capping pattern 124.

Subsequently, bit line structures BLS1 and BLS2may be formed in the cell region CR and the dummy region IR of the substrate 110, and a first preliminary conductive layer, a second preliminary conductive layer, a third preliminary conductive layer, and a preliminary capping insulating pattern for forming the bit line pad BLP in the peripheral circuit region PR of the substrate 110 may be formed on the substrate 110.

Specifically, the first preliminary conductive layer may be formed on the plurality of active regions ACT and the device isolation layer 116. The first preliminary conductive layer may fill the bit line contact trench DC_T and cover the buffer layers 112 and 114.

The second preliminary conductive layer, the third preliminary conductive layer, and the preliminary capping insulating pattern may be sequentially formed on the first preliminary conductive layer.

In an embodiment, each of the first preliminary conductive layer, the second preliminary conductive layer, and the third preliminary conductive layer may contain conductive material. For example, the first preliminary conductive layer may contain polysilicon doped with impurities or a metal such as W, Mo, Au, Cu, Al, Ni, or Co, the second preliminary conductive layer may contain a metal such as Ti, Ta, or the like and/or a metal nitride such as TiN, TaN, or the like, and the third preliminary conductive layer may contain a metal such as W, Mo, Au, Cu, Al, Ni, or Co. However, the number and material of the preliminary conductive layers for forming the bit line structures BLS1 and BLS2are not limited thereto and may be variously changed.

The preliminary capping insulating pattern may contain an insulating material. For example, the preliminary capping insulating pattern may contain, but is not limited to, silicon oxide, silicon nitride, silicon oxynitride, or combinations thereof.

Subsequently, by performing a patterning process on the first preliminary conductive layer, the second preliminary conductive layer, the third preliminary conductive layer, and the preliminary capping insulating pattern sequentially stacked on the substrate 110, bit line structures BLS1 and BLS2 may be formed in the cell region CR and the dummy region IR of the substrate 110, and the bit line pad BLP may be formed in the peripheral circuit region PR of the substrate 110.

The first bit line BL1 and the second bit line BL2 may be formed in the cell region CR and the dummy region IR of the substrate 110, by patterning the first preliminary conductive layer, the second preliminary conductive layer, and the third preliminary conductive layer.

The first bit line BL1 may include the first bit line conductive layer 132a, the second bit line conductive layer 145a, and the third bit line conductive layer 146a, which are sequentially stacked.

The second bit line BL2 may include the first bit line conductive layer 132b, the second bit line conductive layer 145b, and the third bit line conductive layer 146b, which are sequentially stacked.

The first bit line capping pattern 148a and the second bit line capping pattern 148b may be formed on the first bit line BL1 and the second bit line BL2, respectively, by a process of forming the preliminary capping insulating pattern.

The sequentially stacked first bit line BL1 and the first bit line capping pattern 148a may form the first bit line structure BLS1, and the sequentially stacked second bit line BL2 and the second bit line capping pattern 148b may form the second bit line structure BLS2.

By patterning the first preliminary conductive layer positioned in the bit line contact trench DC_T exposing the active region ACT in the cell region CR of a substrate 110, the bit line contact DC may be formed in the bit line contact trench DC_T.

In the peripheral circuit region PR of the substrate 110, the bit line pad BLP may be formed by patterning the first preliminary conductive layer, the second preliminary conductive layer, and the third preliminary conductive layer.

The bit line pad BLP may include the first pad layer 132p, the second pad layer 145p, and the third pad layer 146p, which are sequentially stacked.

The pad capping pattern 148p positioned on a bit line pad BLP may be formed by a process of forming the preliminary capping insulating pattern.

Subsequently, the first spacer 152a, the second spacer 154a, and the third spacer 156a may be sequentially formed on a side surface of the first bit line structure BLS1, and the first spacer 152b, the second spacer 154b, and the third spacer 156b may be sequentially formed on a side surface of the second bit line structure BLS2.

The first spacer 152a, the second spacer 154a, and the third spacer 156a formed on the side surface of the first bit line structure BLS1 may form the first spacer structure BS1, and the first spacer 152b, the second spacer 154b, and the third spacer 156b formed on the side surface of the second bit line structure BLS2 may form the second spacer structure BS2.

The first spacers 152a and 152b may be formed to extend along the side surfaces of the bit line structures BLS1 and BLS2. The first spacers 152a and 152b may cover the upper surfaces of the bit line structures BLS1 and BLS2.

The first spacer 152a of the first spacer structure BS1 may cover a portion of the upper surface of the second buffer layer 114. The first spacer 152b of the second spacer structure BS2 may cover a portion of the upper surface of the second buffer layer 114.

The first spacer 152a of the first spacer structure BS1 and the first spacer 152b of the second spacer structure BS2 may be formed on a side surfaces of the bit line contact DC.

As illustrated in FIG. 17, the first spacer 152b of the second spacer structure BS2 extends along the bottom surface of the bit line contact trench DC_T and may cover a side surface of the bit line contact DC.

Although not shown in detail, the first spacer 152a of the first spacer structure BS1 may be formed on a side surface of the bit line contact DC in substantially the same manner as the first spacer 152b of the second spacer structure BS2.

The second spacer 154a of the first spacer structure BS1 may be formed along the surface of the first spacer 152a of the first spacer structure BS1, and the second spacer 154b of the second spacer structure BS2 may be formed along the surface of the first spacer 152b of the second spacer structure BS2.

As illustrated in FIG. 17, the second spacer 154b of the second spacer structure BS2 may fill the remaining area after the first spacer 152b is formed in the bit line contact trench DC_T.

Although not shown in detail, the second spacer 154a of the first spacer structure BS1 may fill a remaining area of the bit line contact trench DC_T in which the first spacer 152a has been formed, in substantially the same manner as the second spacer 154b of the second spacer structure BS2.

The third spacer 156a of the first spacer structure BS1 may be formed along the surface of the second spacer 154a. The third spacer 156b of the second spacer structure BS2 may be formed along the surface of the second spacer 154b.

Subsequently, a plurality of storage contact trenches BC_T may be formed between bit line structures BLS1 and BLS2positioned in the cell region CR.

A inner wall of the storage contact trench BC_T may be defined by adjacent spacer structures BS1 and BS2, and a bottom surface may be defined by the substrate 110 and the device isolation layer 116.

A plurality of first dummy storage contact trenches DBC1_T and a plurality of second dummy storage contact trenches DBC2_T may be formed between bit line structures BLS1 and BLS2positioned in the dummy region IR.

An inner wall of each of the first dummy storage contact trench DBC1_T and the second dummy storage contact trench DBC2_T may be defined by adjacent spacer structures BS1 and BS2, and a bottom surface of each of the first dummy storage contact trench DBC1_T and the second dummy storage contact trench DBC2_T may be defined by the second buffer layer 114.

In the process of forming each of the first dummy storage contact trench DBC1_T and the second dummy storage contact trench DBC2_T, as a portion of the second buffer layer 114 may be recessed in a concave shape, such that the bottom surfaces of the first and second dummy storage contact trenches DBC1_T and DBC2_T may include a curved surface.

In a patterning step for forming each of the plurality of storage contact trenches BC_T, the plurality of first dummy storage contact trenches DBC1_T, and the plurality of second dummy storage contact trenches DBC2_T, bit line capping patterns 148a and 148b and spacer structures BS1 and BS2 constituting bit line structures BLS1 and BLS2may be used as an etching mask.

Accordingly, in the process step for forming each of the plurality of storage contact trenches BC_T, the plurality of first dummy storage contact trenches DBC1_T, and the plurality of second dummy storage contact trenches DBC2_T, portions of the bit line capping patterns 148a and 148b and the spacer structures BS1 and BS2 constituting the bit line structures BLS1 and BLS2may be removed.

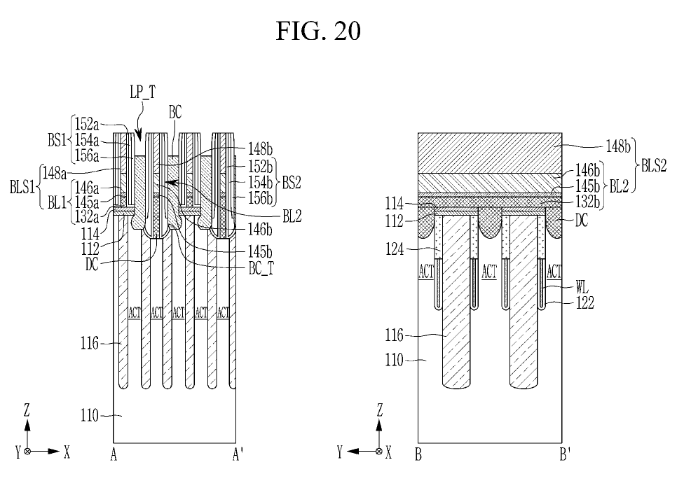

Subsequently, referring to FIGS. 20 to 22, the plurality of storage contacts BC may be formed in the plurality of storage contact trenches BC_T positioned in the cell region CR, and the first dummy storage contact DBC1 and the second dummy storage contact DBC2 may be formed in each of the plurality of first dummy storage contact trenches DBC1_T and the plurality of second dummy storage contact trenches DBC2_T positioned in the dummy region IR.

A process step of forming the plurality of storage contacts BC, the plurality of first dummy storage contacts DBC1, and the plurality of second dummy storage contacts DBC2 may include a step of forming a conductive material to fill each of the plurality of storage contact trenches BC_T, the plurality of first dummy storage contact trenches DBC1_T, and the plurality of second dummy storage contact trenches DBC2_T, and then performing a process of etch back the conductive material until the bit line structures BLS1 and BLS2and the spacer structures BS1 and BS2 are exposed.

In a process step of forming the plurality of storage contacts BC, the plurality of first dummy storage contacts DBC1, and the plurality of second dummy storage contacts DBC2, a portion of the upper surfaces of the bit line structures BLS1 and BLS2and a portion of the upper surfaces of the spacer structures BS1 and BS2 may be removed together.

Here, the conductive material may be, for example, polysilicon, but is not limited thereto.

Accordingly, the storage contact BC may fill a portion of the storage contact trench BC_T, the first dummy storage contact DBC1 may fill a portion of the first dummy storage contact trench DBC1_T, and the second dummy storage contact DBC2 may fill a portion of the second dummy storage contact trench DBC2_T.

The upper surfaces of each of the storage contacts BC, the first dummy storage contact DBC1, and the second dummy storage contact DBC2 may be positioned at a lower level than the upper surfaces of the bit line structures BLS1 and BLS2. For example, the upper surface of each of the storage contact BC, the first dummy storage contact DBC1, and the second dummy storage contact DBC2 may be positioned at a level between the upper surface and the lower surface of each of the bit line capping patterns 148a and 148b constituting the bit line structures BLS1 and BLS2.

Since the storage contact BC, the first dummy storage contact DBC1, and the second dummy storage contact DBC2 are formed together in the same process step, the upper surfaces of each of the storage contact BC, the first dummy storage contact DBC1, and the second dummy storage contact DBC2 may be positioned at substantially the same level.

A remaining area of the storage contact trench BC_T, after the storage contact BC is filled, may be defined as a landing pad trench LP_T.

A remaining area of the first dummy storage contact trench DBC1_T, after the first dummy storage contact DBC1 is filled, may be defined as a dummy landing pad trench DLP_T, and a remaining area of the second dummy storage contact trench DBC2_T, after the second dummy storage contact DBC2 is filled, may be defined as a dam structure trench DS_T.

In an embodiment, before or after a process of forming the plurality of storage contacts BC, the plurality of first dummy storage contacts DBC1, and the plurality of second dummy storage contacts DBC2, a patterning process may be performed on the bit line pad BLP and the pad capping pattern 148p, which are positioned in the peripheral circuit region PR of the substrate 110, to form a peripheral circuit contact trench BPC_T.

The peripheral circuit contact trench BPC_T may penetrate at least a portion of the pad capping pattern 148p and the bit line pad BLP. For example, an inner wall of the peripheral circuit contact trench BPC_T may be defined by the pad capping pattern 148p and the third pad layer 146p, and a bottom surface may be defined by a second pad layer 145p. However, embodiments are not limited thereto, and the configuration defining the inner wall and bottom surface of the peripheral circuit contact trench BPC_T may be variously changed.

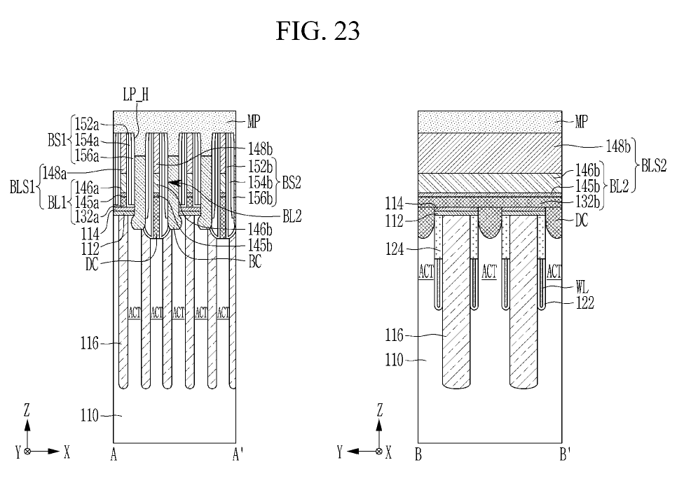

Subsequently, referring to FIGS. 23 to 25, a conductive pattern MP may be formed on the substrate 110 to form the plurality of landing pads LP, the plurality of dummy landing pads DLP, and the plurality of dam structures DS.

Specifically, in the cell region CR, the conductive pattern MP fills the landing pad trench LP_T and may entirely cover the bit line structures BLS1 and BLS2and spacer structures BS1 and BS2.

In the dummy region IR, the conductive pattern MP fills the dummy landing pad trench DLP_T and the dam structure trench DS_T, respectively, and may entirely cover the bit line structures BLS1 and BLS2and spacer structures BS1 and BS2.

Also, in the peripheral circuit region PR, the conductive pattern MP fills the peripheral circuit contact trench BPC_T and may entirely cover the pad capping pattern 148p.

Here, the conductive pattern MP may be, for example, a metal such as tungsten (W), but is not limited thereto.

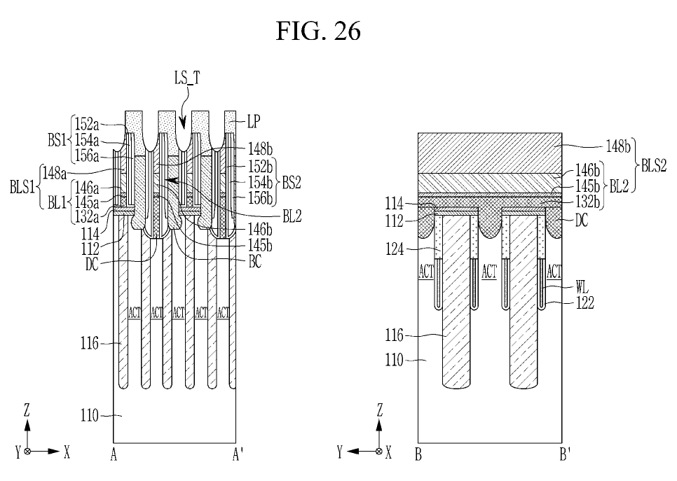

Subsequently, referring further to FIGS. 26 to 29 with 23 to 25, a patterning process may be performed on the conductive pattern MP to form the plurality of landing pads LP in the cell region CR, and the plurality of dummy landing pads DLP and the plurality of dam structures DS in the dummy region IR.

By performing the patterning process on the conductive pattern MP, the peripheral circuit wiring BP and the peripheral circuit contact BPC may be formed in a peripheral circuit region PR.

Specifically, as the patterning process is performed on the conductive pattern MP in the cell region CR of the substrate 110, a landing pad insulating trench LS_T may be defined in an area where a portion of the conductive pattern MP is removed.

The conductive pattern MP may be separated into the plurality of landing pads LP by landing pad insulating trench LS_T. The landing pad insulating trench LS_T may recess a portion of the bit line structures BLS1 and BLS2and a portion of the spacer structures BS1 and BS2.

An inner wall of the landing pad insulating trench LS_T may be defined by the landing pad LP, bit line structures BLS1 and BLS2, and spacer structures BS1 and BS2.

As a patterning process is performed on the conductive pattern MP in the dummy region IR of the substrate 110, the dummy insulating pattern trench DLS_T may be defined in an area where a portion of the conductive pattern MP is removed.

The conductive pattern MP may be separated into the plurality of dummy landing pads DLP by dummy insulating pattern trench DLS_T. The dummy insulating pattern trench DLS_T may recess a portion of the bit line structures BLS1 and BLS2and a portion of the spacer structures BS1 and BS2.

An inner wall of the dummy insulating pattern trench DLS_T may be defined by a dummy landing pad DLP, bit line structures BLS1 and BLS2, and spacer structures BS1 and BS2.

Since a patterning process is performed on the conductive pattern MP in the dummy region IR of the substrate 110, a dam insulating pattern trench LDS_T may be defined in a region where a portion of the conductive pattern MP is removed.

The conductive pattern MP may be separated into the plurality of dam structures DS by dam insulating pattern trench LDS_T. The dam insulating pattern trench LDS_T may recess the first bit line structures BLS1 among the plurality of bit line structures BLS1 and BLS2and the first spacer structures BS1 adjacent thereto.

The conductive pattern MP patterned and remaining in the dummy region IR of the substrate 110 is positioned on the second bit line structures BLS2 among the plurality of bit line structures BLS1 and BLS2and the second dummy storage contact DBC2, and may form the plurality of dam structures DS.

The plurality of dam structures DS is respectively positioned on the second bit line structures BLS2 and may cover the second spacer structures BS2 adjacent thereto.

The plurality of dam structures DS may cover an upper surface of a second dummy storage contact DBC2 positioned between adjacent bit line structures BLS1 and BLS2.

As illustrated in FIGS. 4 and 5, the plurality of dam structures DS may be formed in an island pattern in a plan view, spaced apart from each other in the dummy region IR.

The plurality of dam structures DS may be formed on an end portion BLS2_E of the second bit line structure BLS2 positioned between adjacent first bit line structures BLS1 in the dummy region IR.

The conductive pattern MP that fills the peripheral circuit contact trench BPC_T in the peripheral circuit region PR of the substrate 110 and covers the pad capping pattern 148p may form the peripheral circuit wiring BP and the peripheral circuit contact BPC.

In an embodiment, since the peripheral circuit wiring BP and the peripheral circuit contact BPC are formed in the same process step using the same material, a boundary between the peripheral circuit wiring BP and the peripheral circuit contact BPC may not be visually distinguishable.

However, embodiments are not limited thereto, and since the peripheral circuit wiring BP and the peripheral circuit contact BPC are formed at different process steps using different materials, a boundary may be recognized between them.

In an embodiment, since the landing pad LP, the dummy landing pad DLP, the dam structure DS, the peripheral circuit wiring BP, and the peripheral circuit contact BPC are formed in the same process step using the conductive pattern MP that is blanket-deposited over the substrate 110, they may contain the same material.

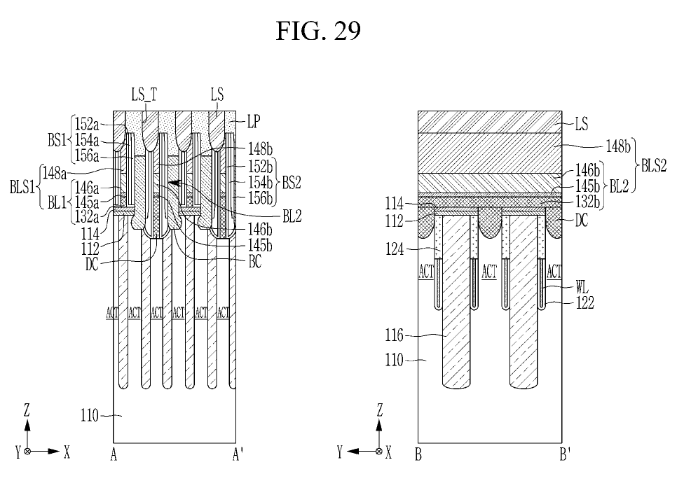

Subsequently, referring to FIGS. 29 to 31, the landing pad insulating pattern LS may be formed in the landing pad insulation trench LS_T in the cell region CR, and the dummy insulating pattern DLS and the dam insulating pattern LDS may be formed in the dummy insulating pattern trench DLS_T and the dam insulating pattern trench LDS_T in the dummy region IR, respectively.

In the cell region CR, the plurality of landing pad insulating patterns LS may be formed on bit line structures BLS1 and BLS2and spacer structures BS1 and BS2, and in the dummy region IR, the plurality of dummy insulating patterns DLS may be formed on bit line structures BLS1 and BLS2and spacer structures BS1 and BS2.

In the dummy region IR, the plurality of dam insulating patterns LDS may be formed on some of the plurality of bit line structures BLS1 and BLS2and some of the plurality of spacer structures BS1 and BS2, respectively. For example, the dam insulating pattern LDS may be formed on each of the plurality of first bit line structures BLS1 and first spacer structures BS1.

Specifically, the step of forming the landing pad insulating pattern LS, the dummy insulating pattern DLS, and the dam insulating pattern LDS may include the step of forming an insulating material on the substrate 110 to fill each of the landing pad insulating trench LS_T, the dummy insulating pattern trench DLS_T, and the dam insulating pattern trench LDS_T, and then removing a portion of the insulating material. For example, the portion of the insulating material may be removed by performing a planarization process.

Here, the insulating material may be, for example, silicon nitride, but is not limited thereto.

Accordingly, the upper surfaces of each of the landing pad insulating pattern LS, the dummy insulating pattern DLS, and the dam insulating pattern LDS become substantially flat, and the upper surfaces of each of them may be positioned at substantially the same level.

The upper surface of the landing pad insulating pattern LS may be positioned at substantially the same level as the upper surface of the landing pad LP, the upper surface of the dummy insulating pattern DLS may be positioned at substantially the same level as the upper surface of the dummy landing pad DLP, and the upper surface of the dam insulating pattern LDS may be positioned at substantially the same level as the upper surface of the dam structure DS.

In an embodiment, since the landing pad insulating pattern LS, the dummy insulating pattern DLS, and the dam insulating pattern LDS are formed in the same process step using an insulating material that is blanket-deposited over the substrate 110, they may contain the same material.

Subsequently, referring to FIGS. 6 to 9, the capacitor CAP including the first electrode 210a, the dielectric film 220a, and the second electrode 230a may be formed on the plurality of landing pads LP and the plurality of landing pad insulating patterns LS in the cell region CR.

The dummy capacitor DCAP including the first dummy electrode 210b, the dummy dielectric film 220b, and the second dummy electrode 230b may be formed on the plurality of dummy landing pads DLP and the plurality of dummy insulating patterns DLS in the dummy region IR.

The dummy dielectric film 220b and the second dummy electrode 230b may be formed on the plurality of dam structures DS and the plurality of dam insulating patterns LDS in the dummy region IR.

The method for manufacturing a semiconductor device according to an embodiment may further include a step of forming a peripheral circuit capping layer 250 on the peripheral circuit wiring BP in the peripheral circuit region PR.

According to the method of manufacturing the semiconductor device in accordance with an embodiment, the plurality of dam structures DS and the plurality of dummy landing pads DLP are formed in the dummy region IR positioned between the cell region CR and the peripheral circuit region PR.

As a result, it is possible to reduce process complexity due to a pattern density difference between the cell region CR and the peripheral circuit region PR, and to make the pattern distribution in the cell region CR and the peripheral circuit region PR more uniform.

Also, since the plurality of dam structures DS are formed in an island pattern spaced apart from each other, it is possible to prevent electrical shorts by preventing exposed bit lines from being directly connected by the dam structures DS, even when spacer structures BS1 and BS2, which surround the end portions of adjacent bit line structures BLS1 and BLS2, are removed during a process of forming the spacer structures. Accordingly, the productivity of semiconductor devices may be improved.

A method for manufacturing a semiconductor device according to an embodiment includes the steps of forming a substrate including a cell region in which a plurality of active regions are defined, a peripheral circuit region surrounding the cell region, and a dummy region positioned between the cell region and the peripheral circuit region, forming a word line in the cell region extending in a first direction across the plurality of active regions, forming a plurality of bit line structures extending in a second direction intersecting the first direction in the cell region and the dummy region and connected to the plurality of active regions, forming a plurality of storage contacts in the cell region connected to the plurality of active regions, forming a plurality of landing pads on the plurality of storage contacts, and forming a plurality of dam structures in the dummy region to overlap at least one of the plurality of bit line structures, wherein the plurality of dam structures are arranged in an island pattern spaced apart from each other, in a plan view .

The step of forming the plurality of landing pad and the step of forming the plurality of dam structures may be performed simultaneously.

A method for manufacturing a semiconductor device according to an embodiment further includes a step of forming a plurality of dummy landing pads in the dummy region, wherein the step of forming the plurality of dummy landing pads may be performed simultaneously with the step of forming the plurality of landing pads and the step of forming the plurality of dam structures.

A method for manufacturing a semiconductor device according to an embodiment further includes a step of forming a plurality of peripheral circuit wirings connected to the plurality of bit line structures in the peripheral circuit region, wherein the step of forming the plurality of peripheral circuit wirings may be performed simultaneously with the step of forming the plurality of landing pads, the step of forming the plurality of dam structures, and the step of forming the plurality of dummy landing pads.

The plurality of dam structures may overlap an end portion of each of the plurality of bit line structures positioned in the dummy region.

While this disclosure has been described in connection with what is presently considered to be practical embodiments, it is to be understood that the present disclosure is not limited to the disclosed embodiments. On the contrary, it is intended that various modifications and equivalent arrangements be included within the spirit and scope of the appended claims.

What is claimed is:

1. A semiconductor device comprising:
a substrate including a cell region in which a plurality of active regions are defined, a peripheral circuit region surrounding the cell region, and a dummy region positioned between the cell region and the peripheral circuit region,
a word line in the cell region, the word line extending in a first direction across the plurality of active regions in the cell region,
a plurality of bit line structures in the cell region and the dummy region, the plurality of bit line structures extending in a second direction that intersects the first direction and being connected to the plurality of active regions,
a plurality of storage contacts in the cell region and connected to the plurality of active regions,
a plurality of landing pads on the plurality of storage contacts,
a plurality of capacitors on the plurality of landing pads, and
a plurality of dam structures in the dummy region, the plurality of dam structures being arranged in an island pattern and being spaced apart from each other, in a plan view, in the dummy region, and
wherein the plurality of dam structures are between the plurality of bit line structures in the dummy region, or
the plurality of dam structures overlap at least one of the plurality of bit line structures in the dummy region.

2. The semiconductor device of claim 1, wherein:
the plurality of dam structures overlap a portion of the plurality of bit line structures in the dummy region.

3. The semiconductor device of claim 2, wherein:
each of the plurality of dam structures is between a corresponding two bit line structures of the plurality of bit line structures in the dummy region, and overlaps an end of a bit line structure between the corresponding two bit line structures, in the dummy region.

4. The semiconductor device of claim 3, wherein:
both side surfaces of each of the plurality of dam structures have a concave shape in a plan view.

5. The semiconductor device of claim 1, wherein:
each of the plurality of dam structures is between a corresponding two bit line structures of the plurality of bit line structures in the dummy region, and does not overlap an end portion of a bit line structure between the corresponding two bit line structures.

6. The semiconductor device of claim 5, wherein:
each of the plurality of dam structures includes a groove that surrounds, in a plan view, the end portion of the bit line structure between the corresponding two bit line structures in the dummy region.

7. The semiconductor device of claim 1, wherein:
the plurality of dam structures includes:
a first dam structure that overlaps an end of a portion of the plurality of bit line structures positioned in the dummy region, and
a second dam structure that extends in the first direction to overlap some of a remaining portion of the plurality of bit line structures positioned in the dummy region, the second dam structure having a line shape in a plan view.

8. The semiconductor device of claim 1, wherein:
a first distance between adjacent ones of the plurality of bit line structures in the first direction is greater than about half a width of each of the plurality of dam structures in the first direction.

9. The semiconductor device of claim 1, further comprising:
a plurality of dummy landing pads positioned in the dummy region,
wherein a distance in the second direction between the plurality of dam structures and the plurality of dummy landing pads is greater than about half a width of each of the plurality of dam structures in the second direction.

10. A semiconductor device comprising:
a substrate including a cell region in which a plurality of active regions are defined, a peripheral circuit region surrounding the cell region, and a dummy region positioned between the cell region and the peripheral circuit region,
a word line in the cell region, the word line extending in a first direction across the plurality of active regions in the cell region,
a plurality of bit line structures in the cell region and the dummy region, the plurality of bit line structures extending in a second direction that intersects the first direction and being connected to the plurality of active regions,
a plurality of storage contacts in the cell region and connected to the plurality of active regions,
a plurality of landing pads on the plurality of storage contacts,
a plurality of capacitors on the plurality of landing pads, and
a plurality of dam structures arranged in as island pattern spaced apart from each other, in a plan view, in the dummy region,
wherein the plurality of bit line structures includes:
a plurality of first bit line structures, each having one end portion thereof positioned in the peripheral circuit region, and
a plurality of second bit line structures that are between the plurality of first bit line structures and that each have one end portion thereof which is positioned in the dummy region, and
wherein the plurality of dam structures are positioned between the plurality of first bit line structures in the dummy region, or
each of the plurality of dam structures is positioned to overlap at least one of the plurality of first bit line structures or the plurality of second bit line structures in the dummy region.

11. The semiconductor device of claim 10, wherein:
the plurality of dam structures includes a plurality of first dam structures, each between a corresponding two of the plurality of first bit line structures that are adjacent to each other in the dummy region.

12. The semiconductor device of claim 11, wherein:
the plurality of dam structures further includes a plurality of second dam structures that overlap the plurality of first bit line structures in the dummy region.

13. The semiconductor device of claim 12, wherein:
the plurality of first dam structures respectively overlap end portions of the plurality of second bit line structures.

14. The semiconductor device of claim 12, wherein:
a width of the plurality of first dam structures in the first direction is different from a width of the plurality of second dam structures in the first direction.

15. The semiconductor device of claim 12, wherein:
a width of the plurality of first dam structures in the second direction is different from a width of the plurality of second dam structures in the second direction.

16. The semiconductor device of claim 12, further comprising:
a spacer structure on both side surfaces of each of the plurality of first bit line structures,
wherein a width of each of the plurality of second dam structures in the first direction is smaller than a sum of a width of each of the plurality of first bit line structures in the first direction and widths of the two spacer structures on the side surfaces of the first bit line structure in the first direction.

17. The semiconductor device of claim 12, wherein:
the plurality of first dam structures and the plurality of second dam structures are arranged in a zigzag pattern in the first direction in a plan view.

18. A semiconductor device comprising:
a substrate including a cell region in which a plurality of active regions are defined, a peripheral circuit region surrounding the cell region, and a dummy region positioned between the cell region and the peripheral circuit region,
a word line in the cell region, the word line extending in a first direction across the plurality of active regions in the cell region,
a plurality of bit line structures in the cell region and the dummy region, the plurality of bit line structures extending in a second direction that intersects the first direction and being connected to the plurality of active regions,
a plurality of storage contacts in the cell region and connected to the plurality of active regions,
a plurality of landing pads on the plurality of storage contacts,
a plurality of capacitors on the plurality of landing pads,
a dummy landing pad in the dummy region,
a plurality of dam structures arranged in an island pattern spaced apart from each other, in a plan view, in the dummy region, and
a plurality of bit line pads spaced apart in the first direction in the peripheral circuit region and connected to the plurality of bit line structures,
wherein the plurality of bit line structures includes:
a plurality of first bit line structures, each having one end portion thereof which is positioned in the peripheral circuit region, the one end portions of the plurality of bit line structures being connected to the plurality of bit line pads, and
a plurality of second bit line structures between the plurality of first bit line structures, each having one end portion thereof which is positioned in the dummy region, and
wherein the plurality of dam structures are between the plurality of first bit line structures in the dummy region and overlap the one end portions of the plurality of second bit line structures.

19. The semiconductor device of claim 18, wherein:
each of the plurality of dam structures has a planar area greater than a planar area of each of the plurality of landing pads and greater than a planar area of the dummy landing pad.

20. The semiconductor device of claim 18, wherein:
the plurality of dam structures is substantially at a same level as a level of the plurality of landing pads and a level of the dummy landing pad, and the plurality of dam structures, the plurality of landing pads, and the dummy landing pad contain the same material.
